(19) United States
(12) Patent Application Publication
(10) Pub. No.: US 2022/0165570 A1
(43) Pub. Date: May 26, 2022

(54) SUBSTRATE FOR REMOVAL OF DEVICES USING VOID PORTIONS

(71) Applicant: The Regents of the University of California, Oakland, CA (US)

(72) Inventors: Takeshi Kamikawa, Santa Barbara, CA (US); Masahiro Araki, Santa Barbara, CA (US); Srinivas Gandrothula, Santa Barbara, CA (US)

(73) Assignee: The Regents of the University of California, Oakland, CA (US)

(21) Appl. No.: 17/434,863

(22) PCT Filed: Mar. 13, 2020
(86) PCT No.: PCT/US20/22735

§ 371 Date: Aug. 30, 2021

Related U.S. Application Data
(60) Provisional application No. 62/817,757, filed on Mar. 13, 2019.

(51) Int. Cl. H01L 21/02; H01L 21/78

(52) U.S. Cl. CPC H01L 21/02647; H01L 21/0254; H01S 2304/12; H01L 21/7806; H01L 21/0262; H01L 21/02458

(57) ABSTRACT

Epitaxial lateral overgrowth (ELO) III-nitride layers are grown on or above an opening area of a growth restrict mask deposited on a substrate, wherein the growth of the ELO III-nitride layers and/or a subsequent regrowth layer form one or more voids. III-nitride device layers are grown on or above the ELO III-nitride layers and/or regrowth layer. Stress is applied to a breaking point at the substrate, with the voids assisting the application of stress, so that a bar of devices comprised of the III-nitride device layers, the ELO III-nitride layers and the regrowth layer is removed from the substrate. The voids release stress from the growth restrict mask, which helps prevent cracks. Decomposition of the growth restrict mask is avoided to prevent compensation of p-type layers.

### CROSS REFERENCE TO RELATED APPLICATIONS

This application claims the benefit under 35 U.S.C. Section 119(e) of the following co-pending and commonly-assigned application:

U.S. Provisional Application Ser. No. 62/817,757, filed on Mar. 13, 2019, by Takeshi Kamikawa, Masahiro Araki and Srinivas Gandrothula, entitled “SUBSTRATE FOR REMOVAL OF DEVICES USING VOID PORTIONS,” attorneys' docket number G&C 30794.0722USP1 (UC 2019-412-1);

which application is incorporated by reference herein.

This application is related to the following co-pending and commonly-assigned applications:

U.S. Utility patent application Ser. No. 16/608,071, filed on Oct. 24, 2019, by Takeshi Kamikawa, Srinivas Gandrothula, Hongjian Li and Daniel A. Cohen, entitled “METHOD OF REMOVING A SUBSTRATE,” attorney's docket number 30794.0653USWO (UC 2017-621-1), which application claims the benefit under 35 U.S.C. Section 365(c) of co-pending and commonly-assigned PCT International Patent Application No. PCT/US18/31393, filed on May 7, 2018, by Takeshi Kamikawa, Srinivas Gandrothula, Hongjian Li and Daniel A. Cohen, entitled “METHOD OF REMOVING A SUBSTRATE,” attorney's docket number 30794.0653WOU1 (UC 2017-621-2), which application claims the benefit under 35 U.S.C. Section 119(e) of co-pending and commonly-assigned U.S. Provisional Patent Application No. 62/502,205, filed on May 5, 2017, by Takeshi Kamikawa, Srinivas Gandrothula, Hongjian Li and Daniel A. Cohen, entitled “METHOD OF REMOVING A SUBSTRATE,” attorney's docket number 30794.0653USP1 (UC 2017-621-1);

U.S. Utility patent application Ser. No. 16/642,298, filed on Feb. 20, 2020, by Takeshi Kamikawa, Srinivas Gandrothula and Hongjian Li, entitled “METHOD OF REMOVING A SUBSTRATE WITH A CLEAVING TECHNIQUE,” attorney's docket number 30794.0659USWO (UC 2018-086-2), which application claims the benefit under 35 U.S.C. Section 365(c) of co-pending and commonly-assigned PCT International Patent Application No. PCT/US18/51375, filed on Sep. 17, 2018, by Takeshi Kamikawa, Srinivas Gandrothula and Hongjian Li, entitled “METHOD OF REMOVING A SUBSTRATE WITH A CLEAVING TECHNIQUE,” attorney's docket number 30794.0659WOU1 (UC 2018-086-2), which application claims the benefit under 35 U.S.C. Section 119(e) of co-pending and commonly-assigned U.S. Provisional Patent Application No. 62/559,378, filed on Sep. 15, 2017, by Takeshi Kamikawa, Srinivas Gandrothula and Hongjian Li, entitled “METHOD OF REMOVING A SUBSTRATE WITH A CLEAVING TECHNIQUE,” attorney's docket number 30794.0659USP1 (UC 2018-086-1);

PCT International Patent Application No. PCT/US19/25187, filed on Apr. 1, 2019, by Takeshi Kamikawa, Srinivas Gandrothula and Hongjian Li, entitled “METHOD OF FABRICATING NONPOLAR AND SEMIPOLAR DEVICES USING EPITAXIAL LATERAL OVERGROWTH,” attorney's docket number 30794.0680WOU1 (UC 2018-427-2), which application claims the benefit under 35 U.S.C. Section 119(e) of co-pending and commonly-assigned U.S. Provisional Patent Application Ser. No. 62/650,487, filed on Mar. 30, 2018, by Takeshi Kamikawa, Srinivas Gandrothula., and Hongjian Li, entitled “METHOD OF FABRICATING NONPOLAR AND SEMIPOLAR DEVICES BY USING LATERAL OVERGROWTH,” attorney docket number G&C 30794.0680USP1 (UC 2018-427-1);

PCT International Patent Application No. PCT/US19/32936, filed on May 17, 2019, by Takeshi Kamikawa and Srinivas Gandrothula, entitled “METHOD FOR DIVIDING A BAR OF ONE OR MORE DEVICES,” attorney's docket number 30794.0681WOU1 (UC 2018-605-2), which application claims the benefit under 35 U.S.C. Section 119(e) of co-pending and commonly-assigned U.S. Provisional Application Ser. No. 62/672,913, filed on May 17, 2018, by Takeshi Kamikawa and Srinivas Gandrothula, entitled “METHOD FOR DIVIDING A BAR OF ONE OR MORE DEVICES,” attorneys' docket number G&C 30794.0681USP1 (UC 2018-605-1);

PCT International Patent Application No. PCT/US19/34686, filed on May 30, 2019, by Srinivas Gandrothula and Takeshi Kamikawa, entitled “METHOD OF REMOVING SEMICONDUCTING LAYERS FROM A SEMICONDUCTING SUBSTRATE,” attorney's docket number 30794.0682WOU1 (UC 2018-614-2), which application claims the benefit under 35 U.S.C. Section 119(e) of co-pending and commonly-assigned U.S. Provisional Application Ser. No. 62/677,833, filed on May 30, 2018, by Srinivas Gandrothula and Takeshi Kamikawa, entitled “METHOD OF REMOVING SEMICONDUCTING LAYERS FROM A SEMICONDUCTING SUBSTRATE,” attorneys' docket number G&C 30794.0682USP1 (UC 2018-614-1);

PCT International Patent Application No. PCT/US19/59086, filed on Oct. 31, 2019, by Takeshi Kamikawa and Srinivas Gandrothula, entitled “METHOD OF OBTAINING A SMOOTH SURFACE WITH EPITAXIAL LATERAL OVERGROWTH,” attorney's docket number 30794.0693WOU1 (UC 2019-166-2), which application claims the benefit under 35 U.S.C. Section 119(e) of co-pending and commonly-assigned U.S. Provisional Application Ser. No. 62/753,225, filed on Oct. 31, 2018, by Takeshi Kamikawa and Srinivas Gandrothula, entitled “METHOD OF OBTAINING A SMOOTH SURFACE WITH EPITAXIAL LATERAL OVERGROWTH,” attorneys' docket number G&C 30794.0693USP1 (UC 2019-166-1);

PCT International Patent Application No. PCT/US20/13934, filed on Jan. 16, 2020, by Takeshi Kamikawa, Srinivas Gandrothula and Masahiro Araki, entitled “METHOD FOR REMOVAL OF DEVICES USING A TRENCH,” attorney's docket number 30794.0713WOU1 (UC 2019-398-2), which application claims the benefit under 35 U.S.C. Section 119(e) of co-pending and commonly-assigned U.S. Provisional Application Ser. No. 62/793,253, filed on Jan. 16, 2019, by Takeshi Kamikawa, Srinivas Gandrothula and Masahiro Araki, entitled “METHOD FOR REMOVAL OF DEVICES USING A TRENCH,” attorneys' docket number G&C 30794.0713USP1 (UC 2019-398-1);

PCT International Patent Application No. PCT/US20/20647, filed on Mar. 2, 2020, by Takeshi Kamikawa and Srinivas Gandrothula, entitled “METHOD FOR FLATTENING A SURFACE ON AN EPITAXIAL. LATERAL GROWTH LAYER” attorney's docket number 30794.0720WOU1 (UC 2019-409-2), which application claims the benefit under 35 U.S.C. Section 119(e) of co-pending and commonly-assigned U.S. Provisional Application Ser. No. 62/812,453, filed on Mar. 1, 2019, by Takeshi Kamikawa and Srinivas Gandrothula, entitled “METHOD FOR FLATTENING A SURFACE ON AN EPITAXIAL LATERAL GROWTH LAYER,” attorneys' docket number G&C 30794.0720USP1 (UC 2019-409-1); and

PCT International Patent Application No. PCT/US20/22430, filed on Mar. 12, 2020, by Takeshi Kamikawa, Srinivas Gandrothula and Masahiro Araki, entitled “METHOD FOR REMOVING A BAR OF ONE OR MORE DEVICES USING SUPPORTING PLATES,” attorney's docket number 30794.0724WOU1 (UC 2019-416-2), which application claims the benefit under 35 U.S.C. Section 119(e) of co-pending and commonly-assigned U.S. Provisional Application Ser. No. 62/817,216, filed on Mar. 12, 2019, by Takeshi Kamikawa, Srinivas Gandrothula and Masahiro Araki, entitled “METHOD FOR REMOVING A BAR OF ONE OR MORE DEVICES USING SUPPORTING PLATES,” attorneys' docket number G&C 30794.0724USP1 (UC 2019-416-1);

all of which applications are incorporated by reference herein.

### BACKGROUND OF THE INVENTION

### 1. Field of the Invention

This invention relates to a substrate for the removal of devices using void portions.

### 2. Description of the Related Art

Many device manufacturers have used free-standing bulk GaN substrates to produce laser diodes (LDs) and light-emitting diodes (LEDs) for lighting, optical storage, and other purposes. GaN substrates are attractive in that it is easy to obtain high-quality III-nitride-based semiconductor layers having low defect densities by homo-epitaxial growth on GaN substrates.

However, GaN substrates, which are typically produced using hydride vapor phase epitaxy (HYPE), are very expensive. As a result, researchers have investigated removing III-nitride-based semiconductor layers from GaN substrates after the device is manufactured. Such a technique would result in a GaN substrate that can be recycled, which would provide a very cheap and high quality GaN substrate and III-nitride-based devices for customers.

Consequently, there is a need for a technique that removes III-nitride-based semiconductor layers from III-nitride-based substrates or layers and hetero-substrates with the III-nitride-based layers in an easy manner.

In one previous technique, a GaN layer is spalled by a stressor layer of metal under tensile strain. See, e.g., Applied Physics Express 6 (2013) 112301 and U.S. Pat. No. 8,450,184, both of which are incorporated by reference herein. Specifically, this technique uses spalling in the middle of the GaN layer.

However, surface morphology on a spalling plane is rough and this technique cannot be controlled at the spalling position. Moreover, this removal method may damage the semiconductor layers due to excess bending in the layer that is being removed, which may result in cracks in unintended directions. Thus, it is necessary to reduce any such damage and surface roughness.

Another conventional technique is the use of photoelectrochemical (PEC) etching of sacrificial layers to remove device structures from GaN substrates, but this takes a long time and involves several complicated processes. Moreover, the yield from these processes have not reached industry expectations.

Thus, there is a need in the art for improved methods of removing III-nitride-based substrates from III-nitride-based semiconductor layers. Moreover, there is a need making a device be readily fabricated in very small size. The present invention satisfies these needs.

### SUMMARY OF THE INVENTION

To overcome the limitations in the prior art described above, and to overcome other limitations that will become apparent upon reading and understanding this specification, the present invention discloses a method of fabricating a substrate with void portions and a method for removing the substrate from one or more device layers using the void portions. In the present invention, there are two different way to make the voids in the ELO III-nitride layers.

In a first method of fabricating the void portions, a growth restrict mask is formed on the surface of a substrate having, for example, a stripe pattern. III-nitride layers are grown by epitaxial lateral overgrowth (ELO) on the substrate through opening areas in the growth restrict mask. The growth of the ELO III-nitride layers is stopped before the ELO III-nitride layers coalesce with each other and/or before the growth restrict mask is covered completely with the ELO III-nitride layers. The growth restrict mask is removed by etching, wherein any exposed areas of the growth restrict mask assists in the etching. After removal of the growth restrict mask, a regrowth layer is grown on the ELO III-nitride layers, which results in void regions created by the etching of the growth restrict mask being embedded in the ELO III-nitride layers and the regrowth layer. A depressed portion at a no-growth region is buried by regrowth layer, which also flattens a surface of the regrowth layer. III-nitride device layers are then grown on the ELO nitride layers and/or the regrowth layer, and additional processes are used to fabricate a device from the III-nitride device layers. Dry etching eliminates parts of the III-nitride device layers, the regrowth layer, the ELO nitride layers and the substrate to expose the void regions. A polymer film, plate, substrate or other stress applying material is used to contact the surface of the substrate from the device side, wherein the stress applying material applies a stress to separate a bar of the device from the substrate. The stress applying material can effectively transmit the stress to a breaking point at an edge of the opening area due to the existence of the void region. After the bar is removed, n-electrodes may be deposited to the back side of the bar, This method is known as the “without the growth restriction mask” method.

In a second method of fabricating the void portions, optimizing the growth condition during the growth of the ELO III-nitride layers can automatically make the voids in the ELO III-nitride layer without removing the growth restrict mask. For example, a low V/III condition results in (11-2-2) facets at the edge of the ELO III-nitride layers, which are inverted taper shapes. After coalescing the ELO III-nitride layers, the inverted taper shapes create voids that are triangular shapes at the coalescence region. Thus, this method can easily make voids without an additional process for making voids. This method is known as the “triangular void” method.

In both methods, cracks, which are caused by the stress from the growth restrict mask, can be avoided because the voids can release the stress effectively. Moreover, decomposition of the growth restrict mask, which can result in excessive doping of an active region and compensation of p-type layers, is avoided.

In the present invention, there are many following advantages;

1. Preventing cracks from occurring in the III-nitride device layers. Cracks occur when the growth restrict mask is buried, due to the difference of the thermal expansion co-efficiency between the growth restrict mask and the III-nitride device layers.

In the “without the growth restriction mask” method, the growth restrict mask is removed, which eliminates this problem. Moreover, the substrate includes the void regions, which can effectively release the stress of the III-nitride semiconductor layers.

In the “triangular void” method, even though the growth restrict mask remains, the triangular shaped voids effectively release the stress in the ELO III-nitride layers, which can prevent cracks from occurring. In this case, the voids, which are placed directly on the growth restrict mask, can effectively release the stress because of the ability to form large voids.

2. Reducing the number of holes at the surface of the regrowth layer. The existence of the holes causes surface roughness. Using an Mg-doped regrowth layer can reduce the number of holes. Moreover, the Mg-doped regrowth layer can bury the depressed region at the no-growth region, which reduces the growth time of the regrowth layer.

3. Obtaining a smooth surface after coalescing the ELO III-nitride layers. Chemical mechanical polishing (CMP) can smooth the surface after coalescence, which promotes a flat surface for the III-nitride device layers, and reduces the in-plane distribution of each layer's thickness.

4. Performing device processes with a flat surface substrate. The substrate can be handled as a conventional wafer, with the void region is completely embedded within the ELO III-nitride layers and regrowth layer.

5. This invention can prevent compensation of p-type layers by the decomposition of the growth restrict mask. Generally, in the ELO method, the growth restrict mask is comprised of SiO₂ or SiN. However, both Silicon (Si) and Oxygen (O) atoms are n-type dopants for GaN. Thus, if the SiO₂ decomposes during the growth of the p-type layers, these atoms compensate the p-type dopant in the p-type layers of GaN.

In the “without the growth restriction mask” method, the growth restrict mask is removed, which eliminates this problem.

In the “triangular void” method, even though the growth restrict mask remains, the ELO III-nitride layers coalesce, which covers the growth restrict mask, and then the p-type layer is grown on the ELO III-nitride layers. This also avoids the compensation of p-type layers by decomposition of the growth restrict mask.

6. An etching process which is conducted to remove bars of the devices from the substrate.

In the “without the growth restriction mask” method, the voids are etched, which facilitates removal of the bars of the devices remove from the substrate.

In the “triangular void” method, the voids have a tall height, and the etching depth can easily reach the top of the void. When the etching depth reaches the top of the voids, the III-nitride device layers on the substrate can be divided into the bar shapes. Less etching time and a reduced amount of etched material provide advantages in mass-production.

7. The present invention can use either a III-nitride substrate or a hetero-substrate, such as sapphire, SiC, LiAlO₂, Si, etc., as long as it enables growth of a III-nitride-based semiconductor layer through a growth restrict mask. In the case using a III-nitride substrate, the present invention can obtain high quality III-nitride-based semiconductor layers and avoid bowing or curvature of the substrate during epitaxial growth due to homo-epitaxial growth. As a result, in case of using a III-nitride substrate can also easily obtain devices with reduced defect density, such as dislocation and stacking faults.

8. The present invention can be used to fabricate devices such as light-emitting diodes (LEDs), laser diodes (LDs), photo-detectors (PD), Schottky barrier diodes (SBDs), metal-oxide-semiconductor field-effect-transistors (MOSFETs), or other opto-electronic devices.

### BRIEF DESCRIPTION OF THE DRAWINGS

Referring now to the drawings in which like reference numbers represent corresponding parts throughout:

FIGS. 1(a), 1(b), 1(c), 1(d), 1(e), 1(f), 1(g), 1(h), 1(i), 1(j) and 1(k) are schematics that illustrate the method without the growth restrict mask.

FIGS. 2(a), 2(b), 2(c), 2(d), 2(e), 2(f) and 2(g) are schematics and scanning electron microscope (SEM) images that illustrate the shapes and dimension of the growth restrict mask, ELO III-nitride layers and no-growth regions,

FIGS. 3(a) and 3(b) are schematics that illustrate polishing the surface of the regrowth layers before growth of the III-nitride device layers

FIGS. 4(a), 4(b), 4(c), 4(d) and 4(e) are schematics that illustrate an alternative to FIGS. 1(a), 1(b), 1(c), 1(d) and 1(e).

FIGS. 5(a) and 5(b) are SEM images that illustrate cracks that occur after the coalescence of the ELO III-nitride layer.

FIGS. 6(a) and 6(b) are schematics that illustrate an alternative to FIGS. 1(d) and 1(e).

FIG. 7 is an SEM mage that illustrates the void regions formed after growing the regrowth layer.

FIG. 8 is an SEM image that illustrates how to eliminate the void regions.

FIGS. 9(a), 9(b), 9(c), 9(d), 9(e) and 9(f) are schematics that illustrate an alternative to FIGS. 1(d), 1(e), 1(f), 1(g) and 1(h).

FIGS. 10(a) and 10(b) are SEM images that illustrate etching below the void region.

FIGS. 11(a) and 11(b) are schematics that illustrate etching below the void region.

FIGS. 12(a), 12(b), 12(c), 12(d) and 12(e) are schematics that illustrate how a bar of devices is removed the substrate.

FIG. 13 is a schematic that illustrates the coating of facets on devices.

FIGS. 14(a), 14(b) and 14(c) are schematics that illustrate how the devices are mounted on the heat sink plate.

FIGS. 15(a) and 15(b) are schematics that illustrate how the devices mounted on heat sink plates are divided.

FIGS. 16(a) and 16(b) are schematics that illustrate how the devices are screened and tested.

FIG. 17 is a schematic that illustrates how the devices are mounted in a TO-can package.

FIG. 18 is a schematic that illustrates how the devices are mounted in a module.

FIGS. 19(a), 19(b), 19(c), 19(d), 19(e), 19(f), 19(g), 19(h), 19(i), 19(j), 19(k), 19(l), 19(m) and 19(n) are schematics that illustrate the method using triangular voids.

FIGS. 20(a) and 20(b) are SEM images that illustrate non-uniform and uniform ELO III-nitride layers grown along the opening areas.

FIGS. 21(a), 21(b) and 21(c) are SEM images and a schematic that illustrate the growth of ELO III-nitride layers from initial layers that forms an inverted taper facet.

FIGS. 22(a), 22(b), 22(c), 22(d), 22(e) and 22(f) are schematics that illustrate an alternative to FIGS. 19(j), 19(k), 19(l), 19(m) and 19(n).

FIG. 23 is a schematic that illustrates how the area for forming a device avoids the center of the void region.

FIG. 24 is a schematic that illustrates the structure of the polymer film.

FIGS. 25(a) and 25(b) are schematics that illustrate the growth restrict mask and its opening areas.

FIGS. 26(a), 26(b), 26(c), 26(d), 26(e), 26(f), 26(g) and 26(h) are schematics that illustrate the use of a growth support layer deposited on the substrate.

FIGS. 27(a), 27(b), 27(c), 27(d), 27(e), 27(f), 27(g) and 27(h) are schematics that illustrate the use of a growth support layer deposited on the substrate.

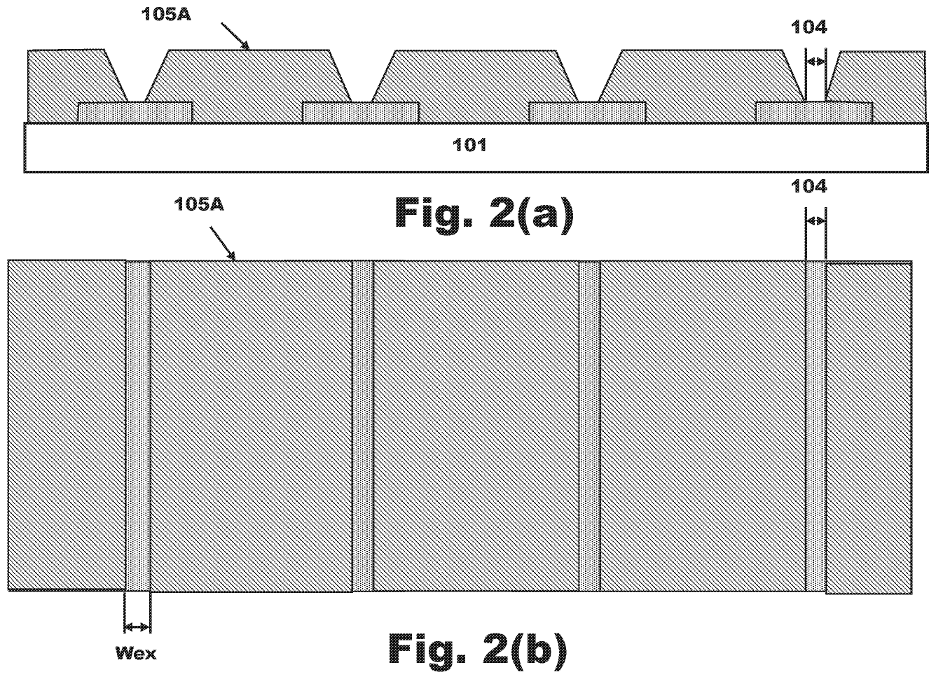

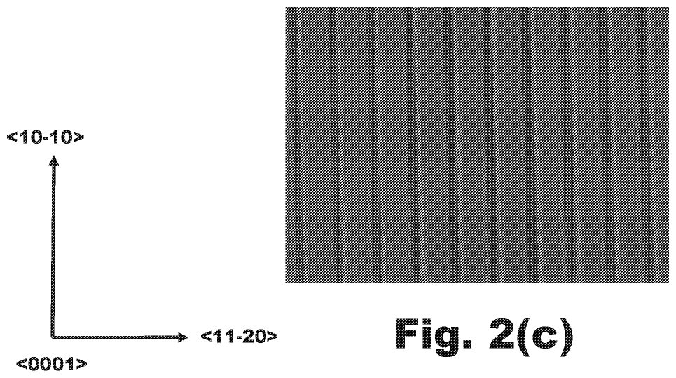

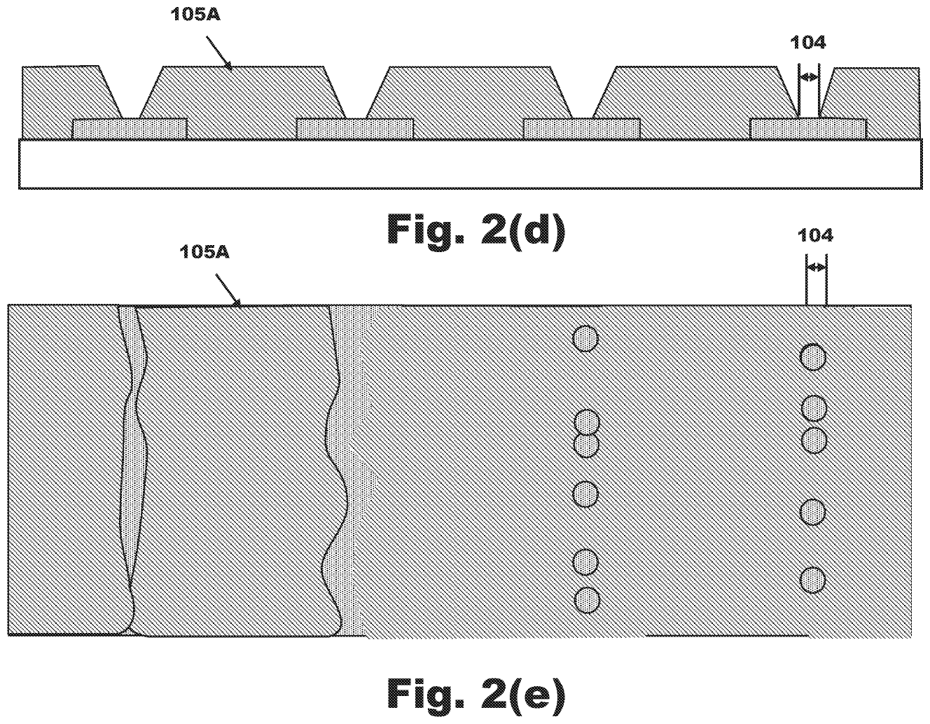

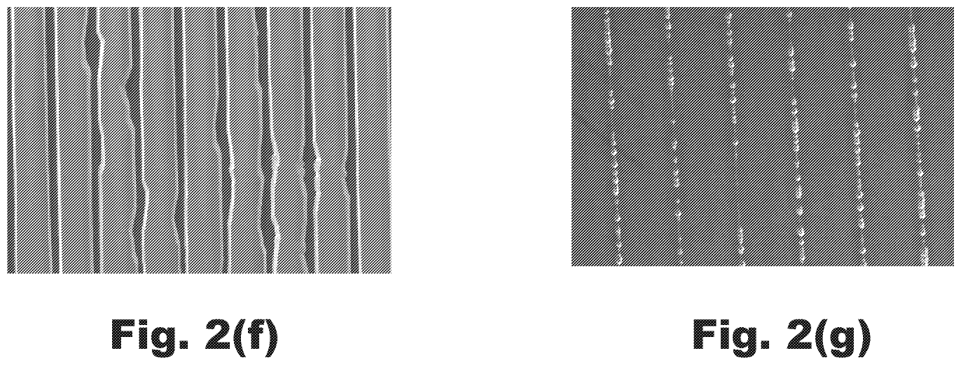

FIG. 2S is a flowchart that illustrates a method for removing a bar of one or more devices from a substrate using void regions.

### DETAILED DESCRIPTION OF THE INVENTION

In the following description of the preferred embodiment, reference is made to a specific embodiment in which the invention may be practiced. It is to be understood that other embodiments may be utilized and structural changes may be made without departing from the scope of the present invention.

A Method Without a Growth Restrict Mask

The following process is directed to a method without a growth restrict mask.

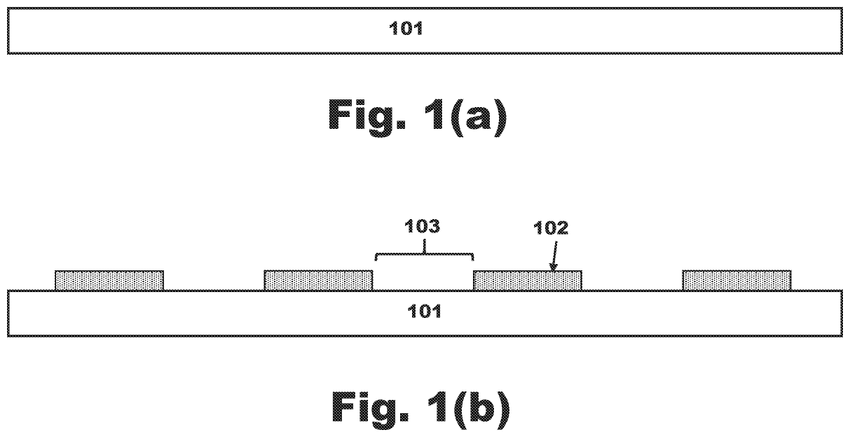

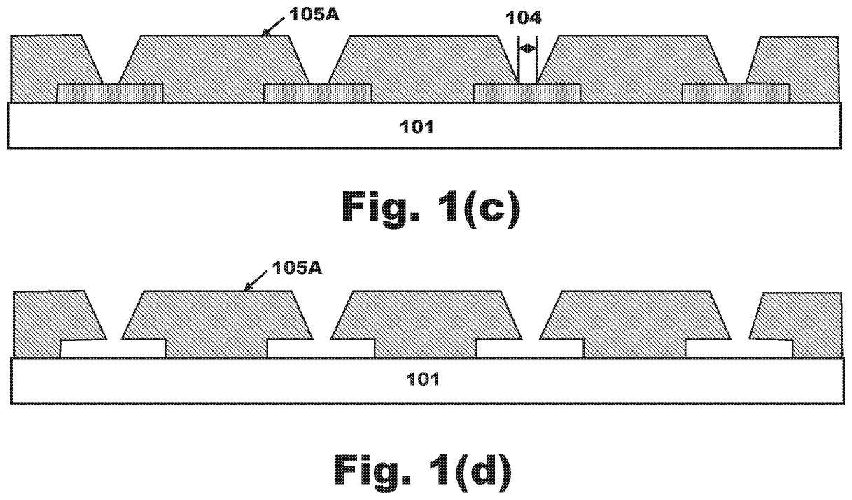

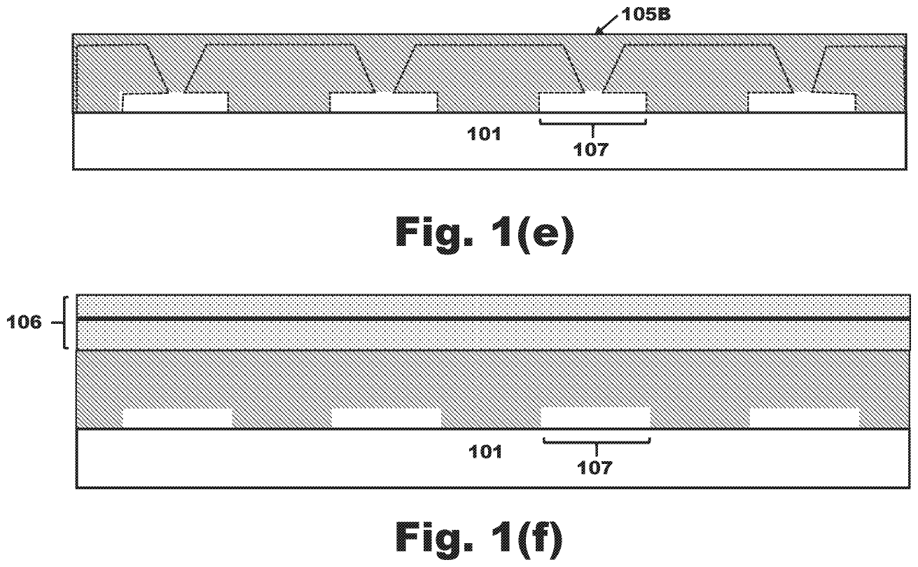

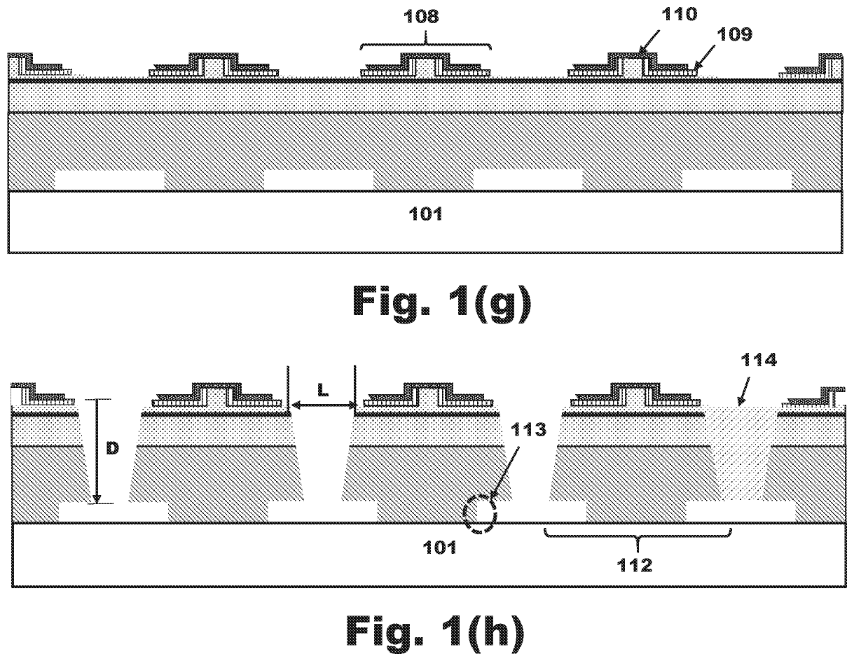

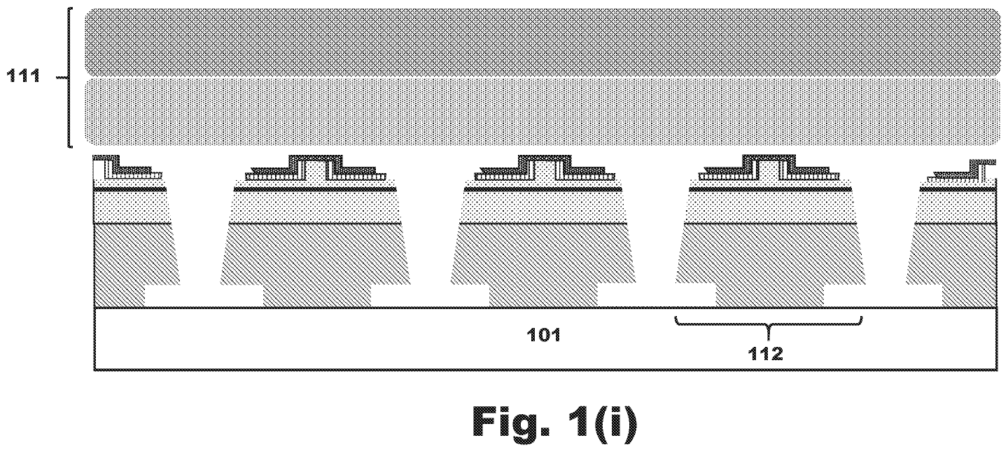

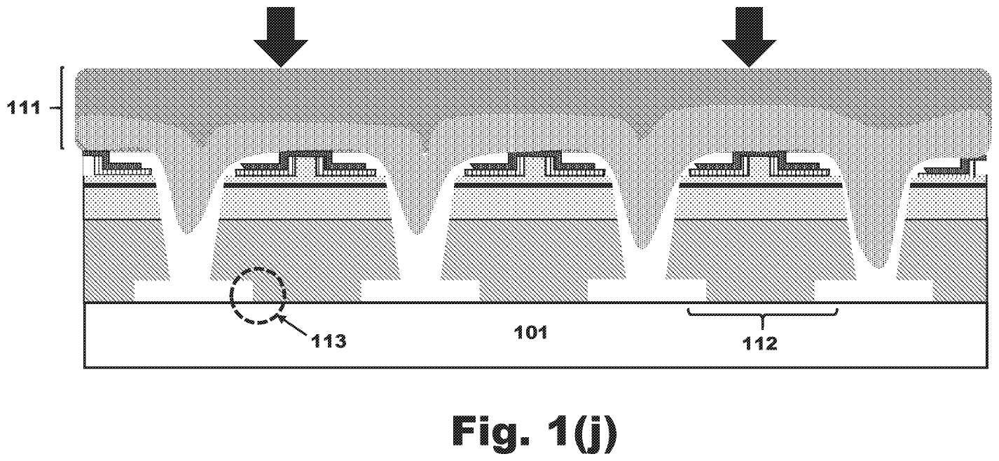

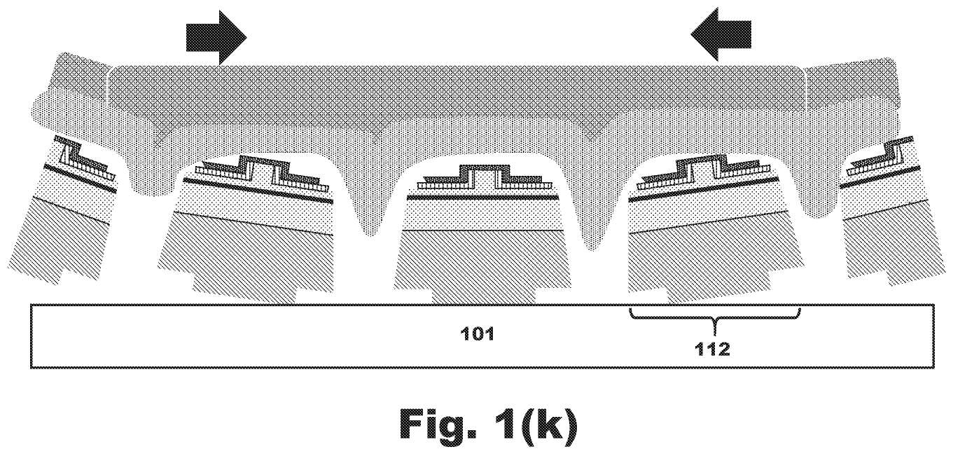

FIGS. 1(a), 1(b), 1(c), 1(d), 1(e), 1(f), 1(g), 1(h), 1(i), 1(j) and 1(k) are schematics that illustrate the method without the growth restrict mask, according to one embodiment of the present invention, These structures include a III-nitride substrate 101, growth restrict mask 102, opening areas 103, no-growth region 104, ELO III-nitride layer 105A, regrowth layer 105B, III-nitride device layers 106, void region 107. ridge structure 108, current blocking layer 109, p-type electrode 110. polymer film 111, bar 112 of devices, breaking point 113, and etched region 114.

These process steps and structures are described in more detail below.

Step 1: Depositing the growth restrict mask 102 on the substrate 101 with a remaining surface exposed by striped opening areas 103 in the growth restrict mask 102, as shown in FIGS. 1(a) and 1(b).

Moreover, the present invention can use various kinds of template substrates 101, such as III-nitride layers on a sapphire substrate 101, Silicon substrate 101, or SiC substrate 101, as well as other substrates 101. For example, it is possible to grow the ELO III-nitride layer 105A directly on a sapphire substrate 101 with the growth restrict mask 102. In these cases, the present invention can obtain almost the same results and effects.

Step 2: Growing the ELO III-nitride layers 105A on the substrate 101 using the growth restrict mask 102, such that the growth extends in a direction parallel to the striped opening areas 103 of the growth restrict mask 102, and the ELO III-nitride layers 105A do not coalesce. The no-growth region 104 may take many shapes depending on the growth conditions of the ELO III-nitride layer 105A, and the shapes and dimension of the growth restrict mask 102, as shown in FIGS. 2(a), 2(b), 2(c), 2(d), 2(e), 2(f) and 2(g) are schematics and scanning electron microscope (SEM) images that illustrate the shapes and dimension of the growth restrict mask. ELO III-nitride layers and no-growth regions,

In FIGS. 2(a), 2(b) and 2(c), the edge of the ELO III-nitride layer 105A is straight. In FIGS. 2(d), 2(e), 2(f) and 2(g), the ELO III-nitride layer 105.A has a winding shape at its edge portion and a part of the ELO III-nitride layer 105A coalesces to an adjacent to ELO III-nitride layer 105A. However, the ELO III-nitride layers 105A do not coalesce. On the right side of FIG. 2(e) and shown in FIG. 2(g), a coalescence of the ELO III-nitride layers 105A. further progresses as compared to the case on the left side of FIG. 2(e) and shown in FIG. 2(f). Every case as shown in FIGS. 2(a), 2(b), 2(c), 2(d), 2(e), 2(f) and 2(g) has at least an exposed region 104, which does not cover the growth restrict mask 102 with the ELO III-nitride layer 105A. Therefore, in following process, the growth restrict mask 102 can be easily removed by wet etching. Etchants easily dissolve the growth restrict mask 102 through an exposed no-growth region 104.

As shown in FIG. 2(b), Wex is the width of the exposed no-growth region 104. It is preferable that Wex is less than 6 μm, so that the void region 107 can be formed properly by the following growth. The wider Wex has a possibility to cause disappearing the void regions 107 because an epitaxial growth can be occurred the area where the growth restrict mask 102 is removed and is exposed the surface of the substrate 101. It is more preferable if the width of the Wex is 3 μm or less.

Step 3: Removing the substrate 101 with the ELO III-nitride layers 105A from the MOCVD reactor, and then removing the growth restrict mask 102 by dry or wet etching method with an etchant, such as hydrofluroide (HF) or buffered HF (BHF).

Step 4: Growing the regrowth layers 105B on the ELO III-nitride layers 105A in order to form void regions 107 and flatten the surface of the layers 105B.

Step 5: Growing the III-nitride device layers 106 on the regrowth layers 105B, as shown in FIG. 1(f), wherein the III-nitride device layers 106 comprise island-like III-nitride layers that can be used to fabricate separate devices.

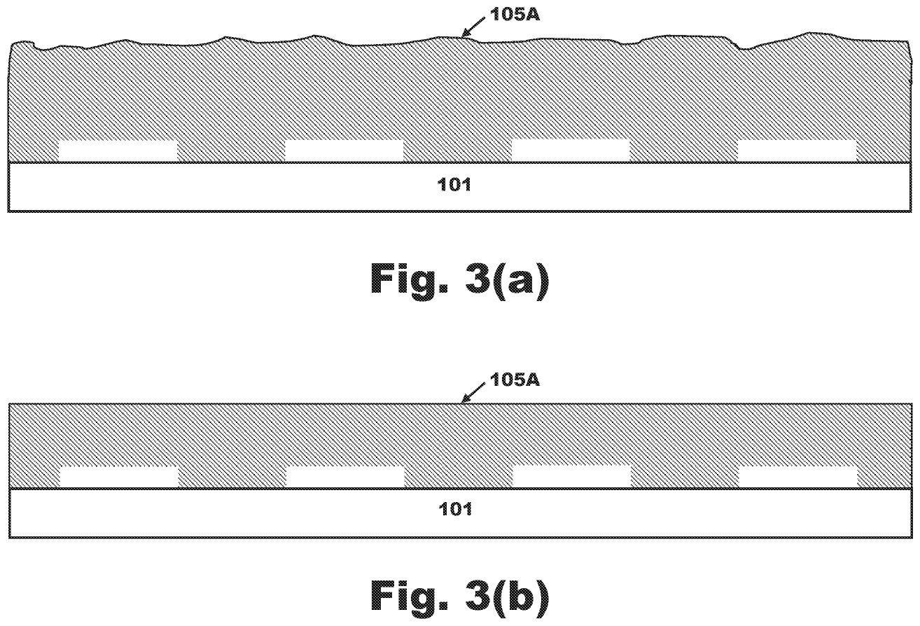

Step 5′: Polishing the surface of the regrowth layers 105B before growth of the III-nitride device layers 106. In the present invention, this is an optional step, as shown in FIGS. 3(a) and 3(b), which are variants of FIG. 1(e). When the surface of the regrowth layers 105B is rough as shown in FIG. 3(a), the surface can be polished by CMP, etc., as shown in FIG. 3(b). This makes for a more uniform distribution of the in-plane distribution of the layers' thicknesses.

Step 6: Fabricating the device at a flat surface region of the III-nitride device layers 106 by conventional methods, wherein a ridge structure 108, current block layer 109, p-electrode 110, pad-electrode, etc., are disposed on the island-like III-nitride device layers 106 at pre-determined positions, as shown in FIG. 1(g).

Step 7: Etching the III-nitride device layers 106, the regrowth layer 105B, and the ELO III-nitride layer 105A, by a conventional dry etch method, as shown in FIG. 1(h).

Step 8: Removing bars 112 of the devices from the substrate 101 by:
Step 8.1: Attaching a polymer film 111 to the bars 112, as shown in FIG. 1(i).
Step 8.2: Applying pressure to the polymer film 111 and the substrate 101, as shown in FIG. 1(j).
Step 8.3: Reducing the temperature of the polymer film 111 and the substrate 101 while the pressure is applied.
Step 8.4: Utilizing the different of thermal coefficient between the polymer film 111 and the substrate 101 for removing the bars 112 of the devices, as shown in FIG. 1(k).

Step 9: Fabricating an n-electrode on the bars 112 of the devices.

Step 10: Breaking the bars 112 into separate devices.

Step 11: Mounting each device on a heat sink plate.

Step 12: Coating the facets of a laser diode device.

Step 13: Dividing the coating bar.

Step 14: Screening the devices.

Step 15: Mounting the devices on or into the packages.

These steps are explained in more detail below.

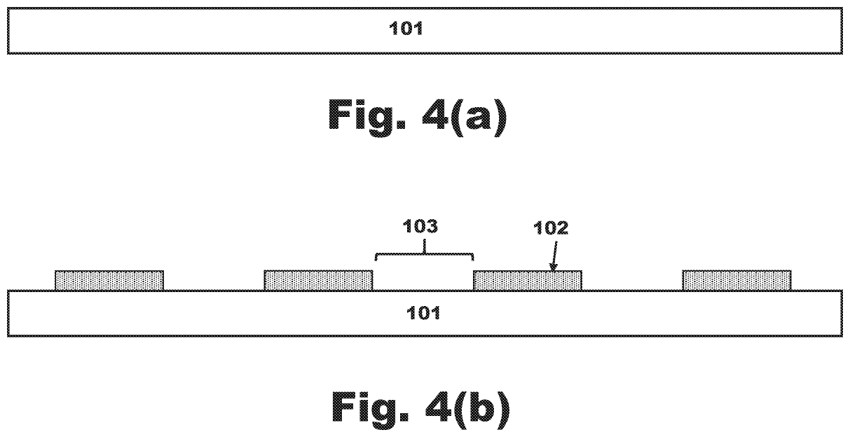

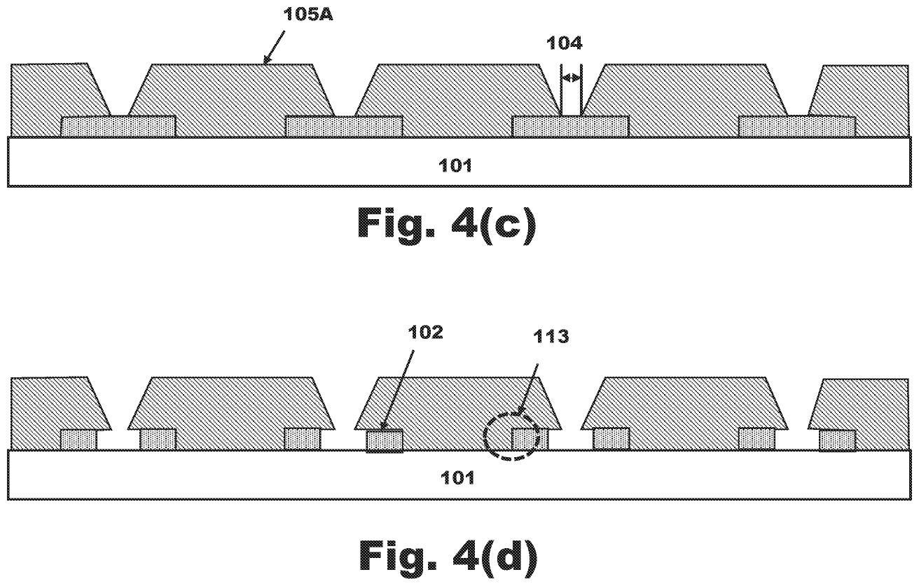

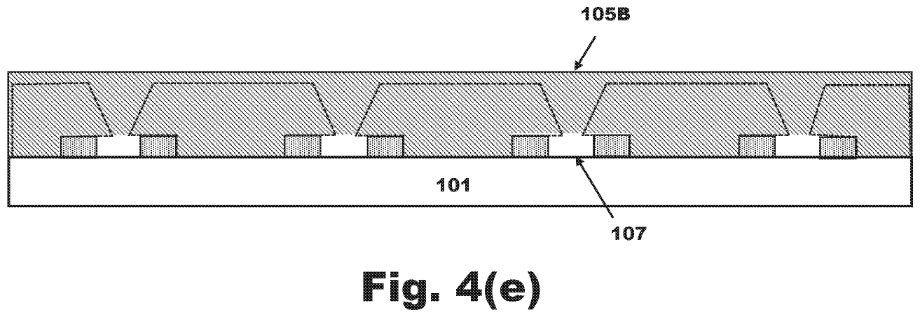

There is another option as shown in FIGS. 4(a), 4(b), 4(c), 4(d) and 4(e), which are schematics that illustrate an alternative to FIGS. 1(a), 1(b), 1(c), 1(d) and 1(e). This method is almost the same process described above except for Step 3. In this method, a part of the growth restrict mask 102 remains at Step 3 by controlling the time for dissolving the growth restrict mask 102 as shown in FIG. 4(d). The short dissolving time can remove only an area under the no-growth region 104.

Even in this case, the voids 107 can be included between the 101 substrate surface and the ELO III-nitride layer 105A surface. Before Step 8, the remaining growth restrict mask 102 can be removed, as shown in FIG. 4(d), by wet etching with HF or BHF. In this case, the voids 107 can effectively release the stress from the growth restrict mask 102.

Growing the III-nitride device layers 106 on the ELO III-nitride layer 105A cause the deformation of the edges of the voids 107 depending on growth conditions and time. The part of the edge of the voids 107 is shown in FIG. 4(d) as 113. The remaining growth restrict mask 102 avoids the deformation of the edge of the voids 107. This can improve the yield when removing the bars 112 from the substrate 101, due to making the shape of the edges of the voids 107 uniform.

Step 1: Depositing the Growth Restrict Mask on the Substrate

As shown in FIGS. 1(a)-1(c), a c-plane GaN substrate 101 is patterned with a growth restrict mask 102 comprised of SiO₂. The growth restrict mask 102 includes stripes along a <10-10> axis separated by opening areas 103, although other axes may be used as well.

The width of the stripes in the growth restrict mask 102 is 30 μm-80 μm, and more preferably, 30 μm-60 μm. The width of the opening areas 103 is 2 μm-60 μm, and more preferably, 4 μm-40 μm.

Moreover, these techniques also can be used with a GaN template, which is grown as a GaN underlayer of 2-6 μm on a hetero-substrate 101. Alternatively, the GaN underlayer may be formed on the growth restrict mask 102.

Step 2: Growing the ELO III-nitride Layers on the Substrate Using the Growth Restrict Mask

ELO III-nitride layers 105A are grown in the opening areas 103 of the growth restrict mask 102 on an exposed surface of the substrate 101 or template. Preferably, the ELO III-nitride layers 105A do not coalesce on top of the growth restrict mask 102, and remain separated from each other.

MOCVD is used for the epitaxial growth of the ELO III-nitride layer 105A. Trimethylgallium (TMGa) is used as the III elements source; ammonia (NH₃) is used as the raw gas to supply nitrogen; and hydrogen (H₂) and nitrogen (N₂) are used as a carrier gas of the 111 elements sources. It is important to include hydrogen in the carrier gas to obtain a smooth surface to the epilayers. The thickness of the ELO III-nitride layer 105A is about 3 μm-100 μm. The ELO III-nitride layer 105A may comprise a GaN or AlGaN layer in order to obtain a smooth surface.

Step 3: Removing the Substrate from the MOCVD Equipment

The substrate 101 with the ELO III-nitride layer 105A is removed from the MOCVD reactor, in order to remove the growth restrict mask 102. The growth restrict mask 102 is removed by wet etching with HF, BHF, etc.

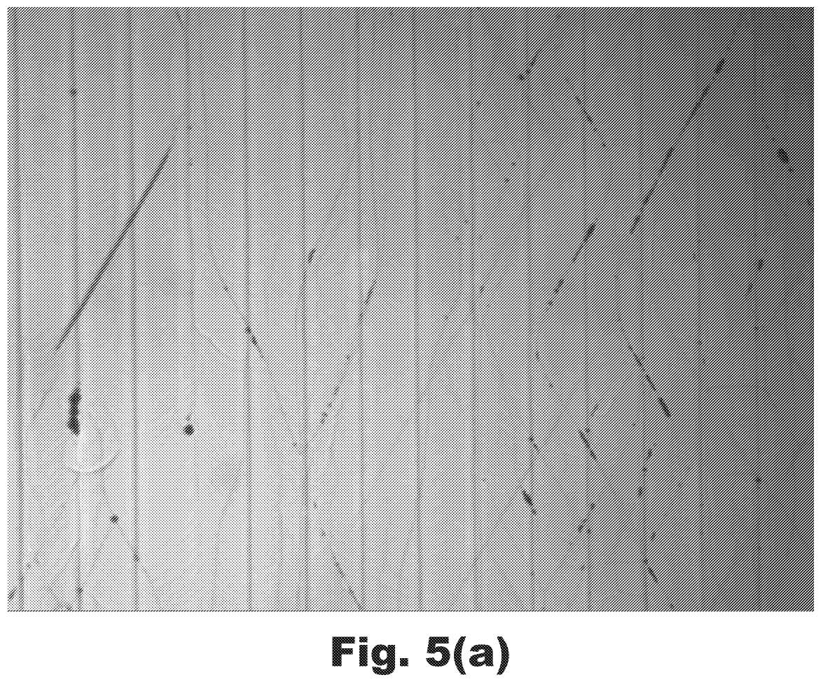

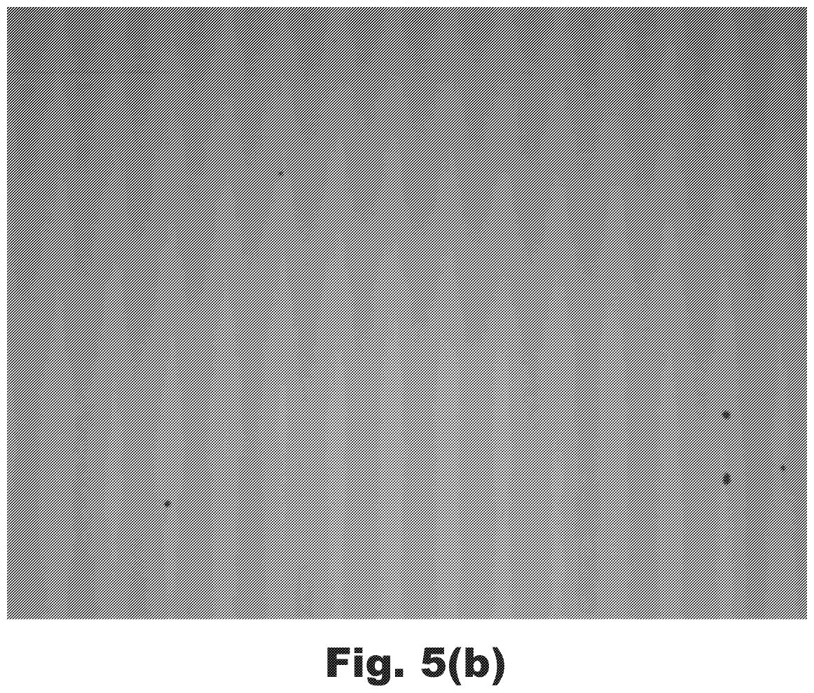

This step is important, because many cracks happen after the coalescence of the ELO III-nitride layer 105A when the growth restrict mask 102 is not removed, as shown in FIGS. 5(a) and 5(b), which are SEM images that illustrate cracks that occur after the coalescence of the ELO III-nitride layer 105A. The cracks shown in FIG. 5(a) are m-plane, which are easy to break; FIG. 5(b) shows a surface with no cracks.

For example, generally using SiO₂ as a growth restrict mask 102 has a lower thermal expansion co-efficient than an III-nitride layer 105A, 105B, 106. The difference of the thermal expansion co-efficient causes the occurrence of the cracks in the III-nitride layers 105A, 105B, 106. The timing of the occurrence of the cracks is when the growth restrict mask 102 is fully covered by the ELO III-nitride layer 105A. Therefore, the ELO III-nitride layer 105A is stopped before the growth restrict mask 102 is fully covered.

By doing this, there are two advantages: one is that it is easy to remove the growth restrict mask 102 by wet etching through the space between the bars 112; another is that the void regions 104 remain after the growth of the regrowth layer 105B, which makes for internal stress release, and can reduce the occurrence of cracking.

Step 4: Growing the Regrowth Layers on the ELO III-nitride Layers in Order to Form Void Regions and Flatten the Surface of the Layers

In this step, the regrowth layers 105B are grown on the ELO III-nitride layers 105A to form void regions 107, as shown in FIG. 1(e). An unintentionally doped (UID) layer or Si-doped layer can be used as a regrowth layer 105B.

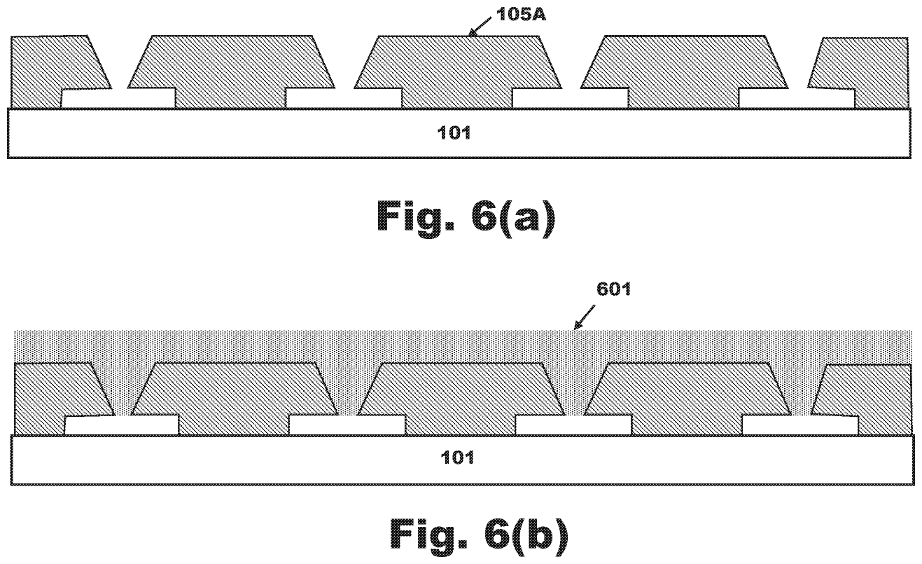

In addition, an Mg-doped layer or co-doped of Mg and Si layer 301 can be used as a regrowth layer 105B, as shown in FIGS. 6(a) and 6(b), which are schematics that illustrate an alternative to FIGS. 1(d) and 1(e), respectively. The growth of a III-nitride layer containing Mg effectively buries a depressed area at the no-growth region 104.

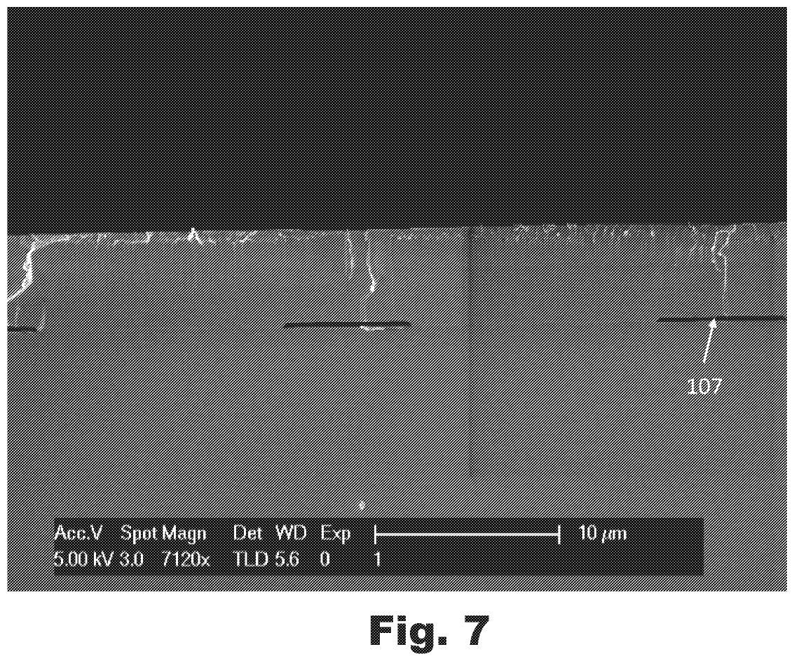

As shown in FIG. 7, which is an SEM image, the void regions 107 could be formed after growing the regrowth layer 105B.

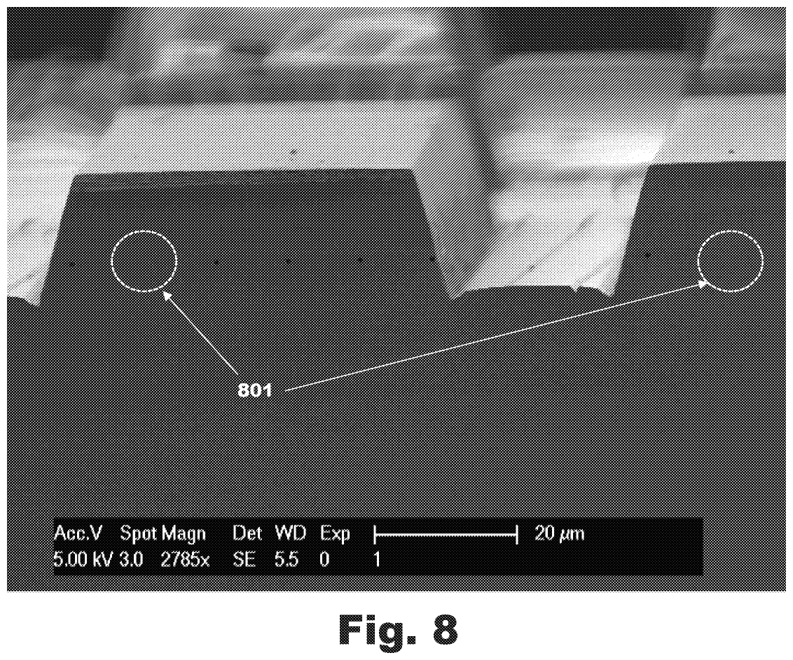

However, it has a possibility to eliminate the void regions 107, depending on the growth conditions and dimensions of the growth restrict mask 102, as shown in the SEM image of FIG. 8. When the size of the void region 107 is smaller than a pre-determined size, the regrowth layer 10513 buries the void region 107 as illustrated by 801. It has been found that an Mg-doped layer or a co-doped layer of Mg and Si have the effect of allowing the void region 107 to remain after the growth of the regrowth layer 1058.

Step 5: Growing III-nitride Device Layers on the Regrowth Layer

As shown in FIG. 1(f), the substrate 101, following removal of the growth restrict mask 102, is loaded into a chamber of the MOCVD reactor, wherein MOCVD is used for the epitaxial growth of the III-nitride device layers 106. Trimethylgallium (TMGa), trimethylindium (TMIn) and triethylaluminium (TMAl) are used as III elements sources; ammonia (NH₃) is used as the raw gas to supply nitrogen; and hydrogen (H₂) and nitrogen (N₂) are used as a carrier gas of the III elements sources. It is important to include hydrogen in the carrier gas to obtain a smooth surface for the epi-layers.

Saline and Bis(cyclopentadienyl)magnesium (Cp₂Mg) are used as n-type and p-type dopants. The pressure setting typically is 50 to 760 Torr. The III-nitride device layers 106 are generally grown at temperature ranges from 700 to 1250° C.

For example, the growth parameters include the following: TMG is 12 sccm, NH₃ is 8 slm, carrier gas is 3 slm, SiH₄ is 1.0 sccm, and the V/III ratio is about 7700. These growth conditions are only one example, and the conditions can be changed and optimized for each of above described layers.

Step 5′: Polishing the Surface of the Substrate

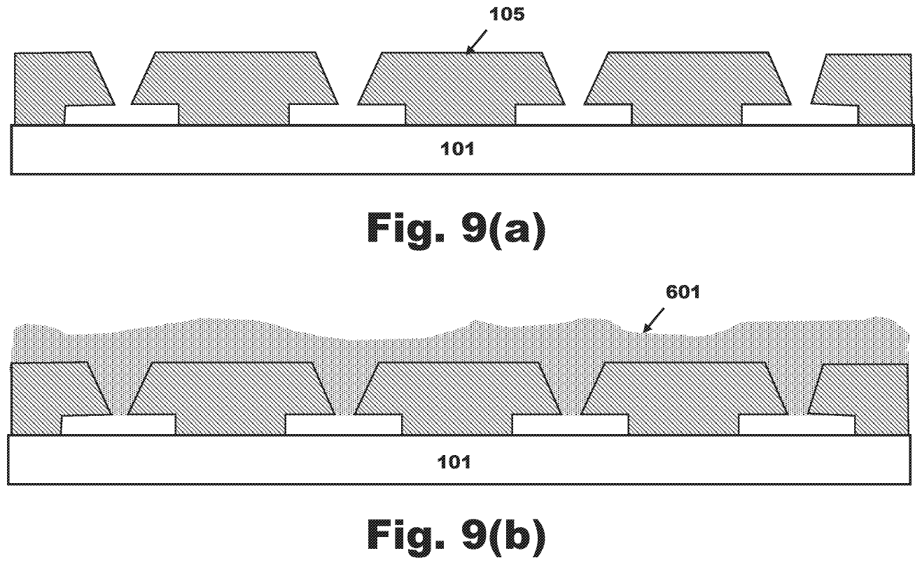

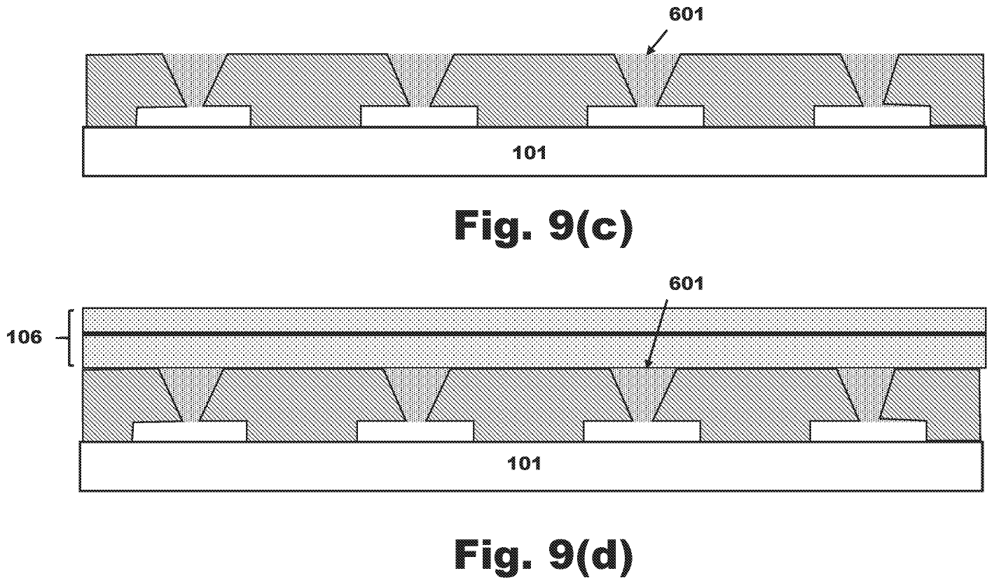

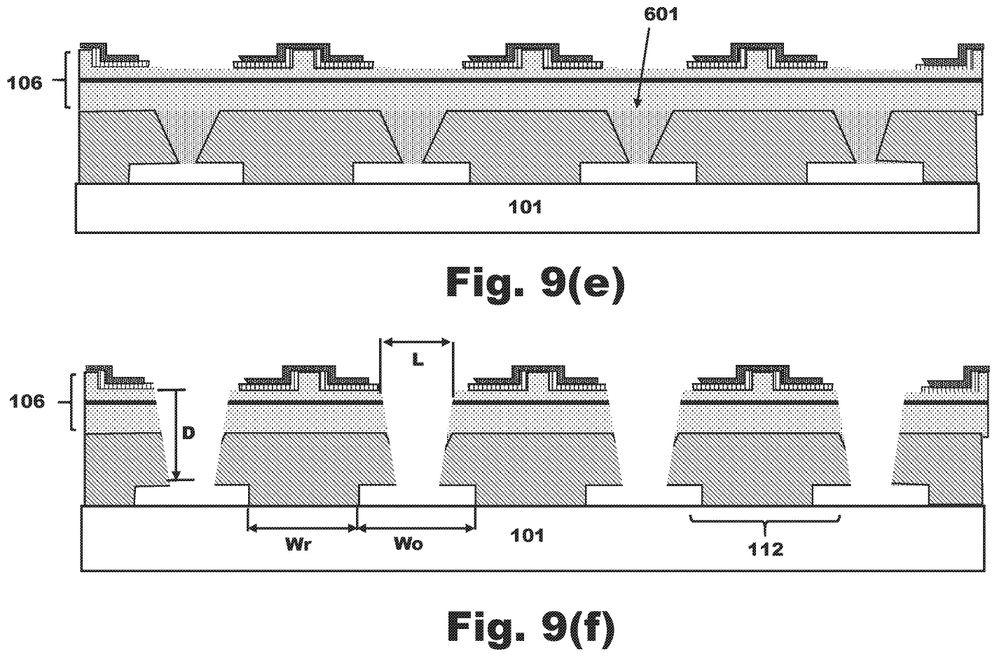

There can be another optional step, as shown in FIGS. 3(a) and 3(b), which are variants of FIG. 1(e), where the surface is polished by CMP, etc. FIGS. 9(a), 9(b), 9(c), 9(d), 9(e) and 9(f) are schematics that illustrate an alternative to FIGS. 1(d), 1(e), 1(f), 1(g) and 1(h). Specifically, FIGS. 9(a), 9(b) and 9(c) illustrate another variant of FIGS. 1(d) and 1(e), wherein polishing reduces the in-plane distribution of the thickness of each layer.

Step 6: Fabricating the Device on the III-nitride Device Layers

After the regrowth layer 105B, the surface of is fiat, and can be used a conventional device processes, such as a dry etching process, a wet etching process, a photolithography process, a deposition process, and so on.

In one embodiment, these above processes can be used to make a ridge structure 108 for a laser diode device, and a p-electrode 110 structure for LEDs and power devices (such as SBDs, MOSFETs, photo diode etc.).

The ridge process used for the laser diode device is described in more detail below. The ridge depth (from the surface to the ridge bottom) is in the p-GaN guide layer. The ridge depth is pre-determined before dry etching is performed, based on simulation or previous experimental data. The present invention can adapt any device on the regrowth layer 105B.

The p-electrode 110 may be comprised of one or more of the following materials: Pd, Ni, Ti, Pt, Mo, W, Ag, Au, etc. For example, the p-electrode may comprise Pd—Ni—Au (with thicknesses of 3-30-300 nm). These materials may be deposited by electron beam evaporation, sputter, thermal heat evaporation, etc. In addition, the p-electrode 110 is typically deposited on the ITO cladding layer.

Step 7: Etching the III-nitride Device Semiconductor Layer, the Regrowth Layer, and the ELO III-nitride Layer

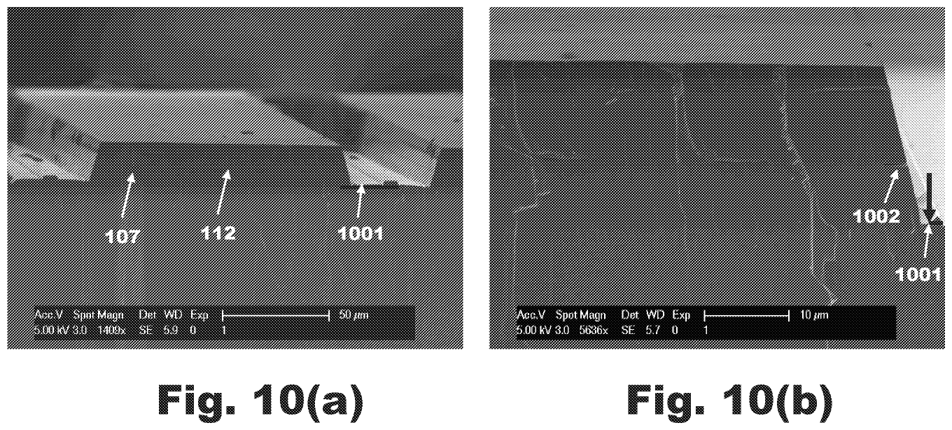

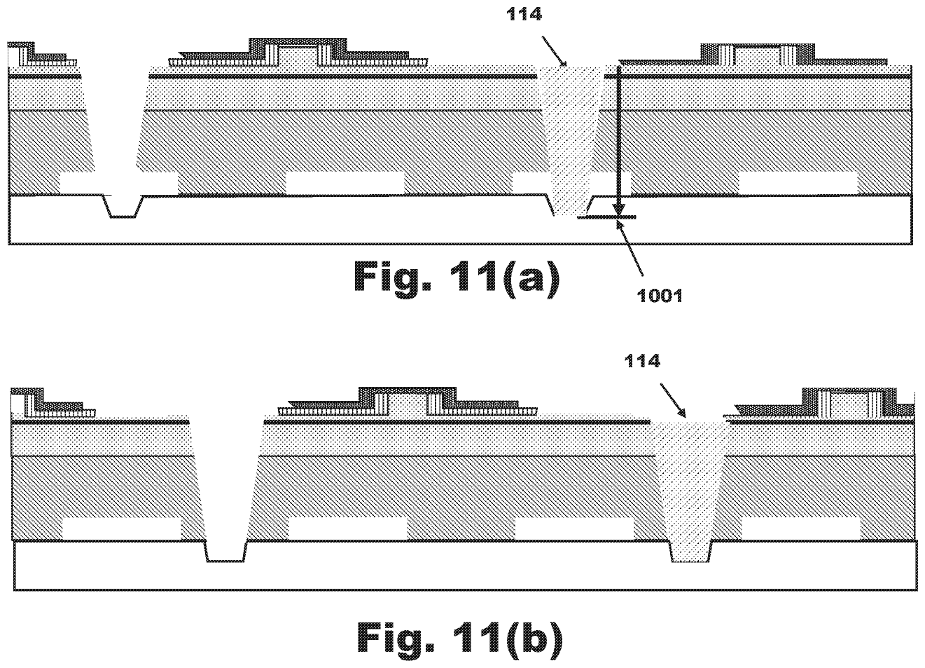

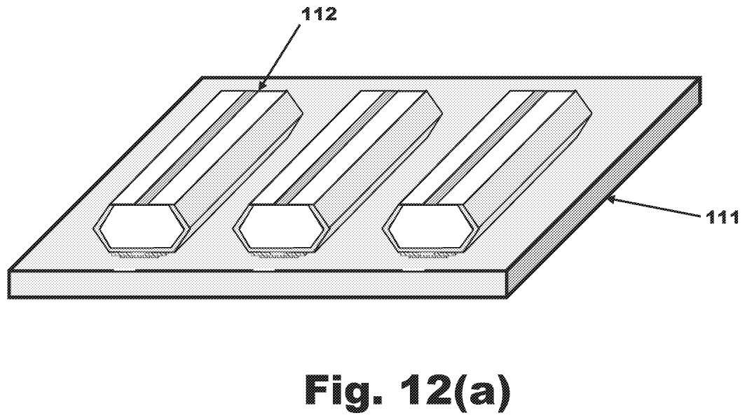

The etching of the III-nitride device layers 106, the regrowth layer 105B, and the ELO III-nitride layer 105A can be performed by a conventional dry etch method, as shown in FIG. 1(h). The depth of the etching is at least to the void region 107 exposed by this etching. It is preferable that the end point of this etching 901 is below the void region 107, as shown in FIGS. 10(a) and 10(b), which are SEM images that illustrate etching 1001, 1002 below the void region 107, and FIGS. 11(a) and 11(b), which are schematics that illustrate etching 1001 below the void region. By doing this, it is easy to remove the bars 112 of the devices from the substrate 101, because the stress from polymer films 111, plates and substrates can effectively be applied to the breaking point 113.

When etching, the etched region 114, as shown in FIGS. 1(h), 10(a) and 11(a), may expose the void regions 107. On the other hand, as shown in FIGS. 10(b) and 8, the etched region 114 may not expose the void region 107. When considering the removal of the bar 112, it is much preferable that the bar 112 has a void region 107 on at least one side of the bar 112.

Step 8: Removing the Bar of the Device from the Substrate

This step describes the removal of the bar 112, which can be adapted from several methods. To remove the bar 112, stress is applied to the breaking point 113 in a direction indicated by arrows shown in FIG. 1(k). The material which applies the stress can be polymer films 111, plates, substrates, etc. A method using a polymer tape 111 is described herein, but the invention is not limited to that method. Furthermore, the stress being applied can utilize thermal expansion, mechanical force, etc.

In this step, to remove the bars 112, the stress is applied from the polymer films 111, plates, substrates, etc., to the bars 112. At that moment, the bars 112 slightly move from the stress being applied. Thus, the etching width L, as shown in FIG. 1(h), needs at least 2 μm, and more preferably, 5 μm. The definition of L is the distance between two adjacent bars 112 at the top of the bars 112, as shown in FIG. 1(h).

From here, the procedure of removing the bars 112 is explained using FIGS. 1(i), 1(j) and 1(k).

Step 8.1 comprises attaching a polymer film 111 to the bar 112, as shown in FIG. 1(i).

Step 8.2 comprises applying pressure to the polymer film 111 and the substrate 101, as shown in FIG. 1(j). The aim of applying pressure is to put the polymer film 111 in-between the bar 112. The polymer film 111 is softer than the bar 112, so the polymer layer 111 can easily surround the bar 112. Preferably, the polymer film 111 is heated in order to soften it, which makes it easier for the polymer film 111 to cover the bar 112. The force from the polymer film 111 is efficiently applied to the breaking point 113.

Step 8.3 comprises reducing the temperature of the film 111 and the substrate 101 while maintaining the applied pressure. It is not necessary to increase the applied pressure during the changing temperature.

Step 8.4 comprises utilizing the differences in thermal coefficients between the polymer film 111 and the substrate 101 for removing the bar 112 of the device.

As shown in FIG. 1(k), the polymer film 111 shrinks as the temperature decreases. As a result, the bottom of the polymer film 111 is lower than the top of the bar 112, as shown in FIG. 1(j). In this case, the polymer film 111 can apply pressure in a horizontal direction at a side facet of the bar 112. This pressure applied at the side facet allows the bar 112 to be effectively removed from the substrate 101, because the pressure is finally applied to the breaking point 113 by making the void region 107. During low temperatures, the polymer film 111 maintains the applied pressure from the top of the film 111 to the bar 112. By doing this, the present invention can remove the bar 112 from the substrate 101 utilizing the void regions 107.

Various methods may be used to reduce the temperature. For example, the substrate 101 and the polymer film 111 can be put into liquid N₂ (for example, at 77° K) at the same time while applying pressure. The temperature of the substrate 101 and film 111 can also be controlled with a piezoelectric transducer.

Moreover, a plate that applies pressure to the polymer film 111 can be cooled to a low temperature before and/or during contact with the polymer film 111. By doing this, the polymer film 111 is cooled and can apply pressure to the bar 112 due to a large thermal expansion coefficient.

When reducing the temperature, the substrate101 and the film 111 may be wetted by atmospheric moisture. In this case, the temperature reduction can be conducted in a dry air atmosphere or a dry N₂ atmosphere, which avoids the substrate 101 and the film 111 getting wet.

Thereafter, the temperature increases, for example, to room temperature, and the pressure is no longer applied to the film 111 At that time, the bar 112 has been already removed from the substrate 101, and the polymer film 111 is then separated from the substrate 101. When using a polymer film 111, especially a polymer film 111 having adhesive, the devices or chips can be removed using the polymer film 111 in an easy and quick manner.

This method of using the adhesive film 111 and the substrate 101 with ELO III-nitride layer 105A can be repeatable many times. If some bars 112 remain on the substrate 101, repeating this method allows the remaining bars 112 to be completely removed from the substrate 101, even for wafer of 2 inches, 4 inches and or more in size.

Step 9: Depositing an n-electrode

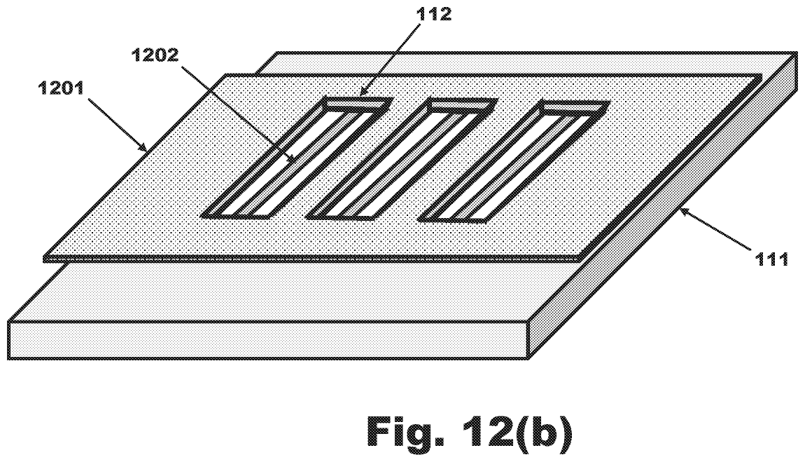

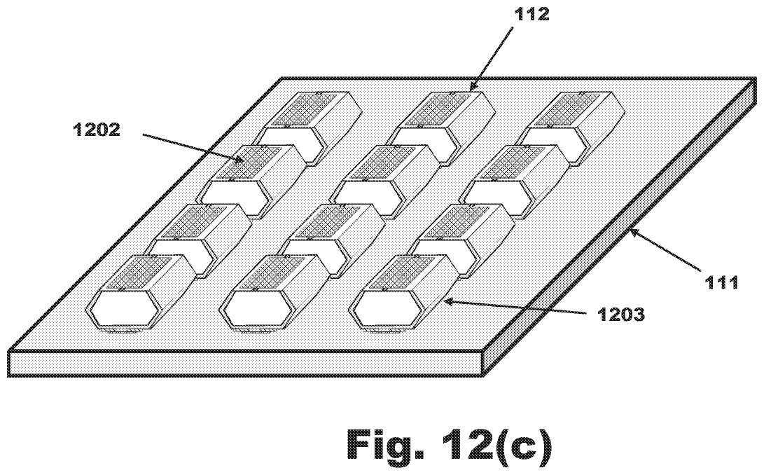

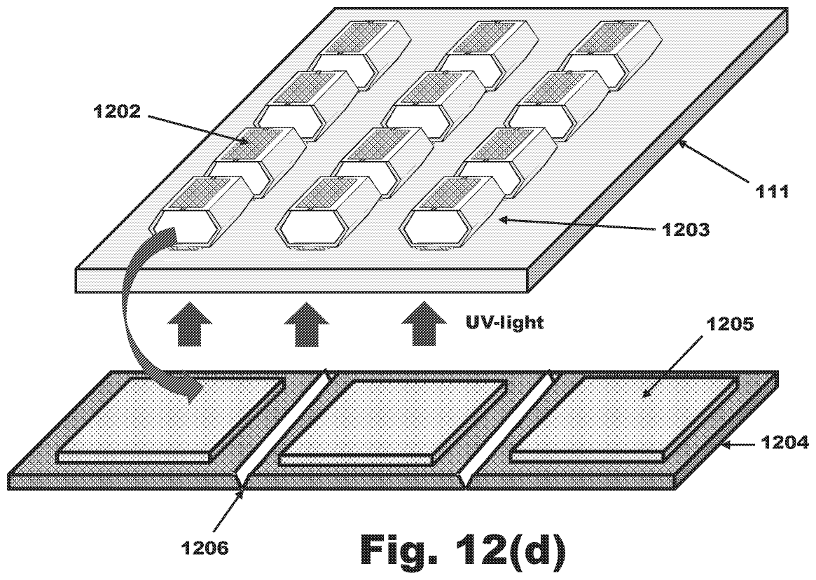

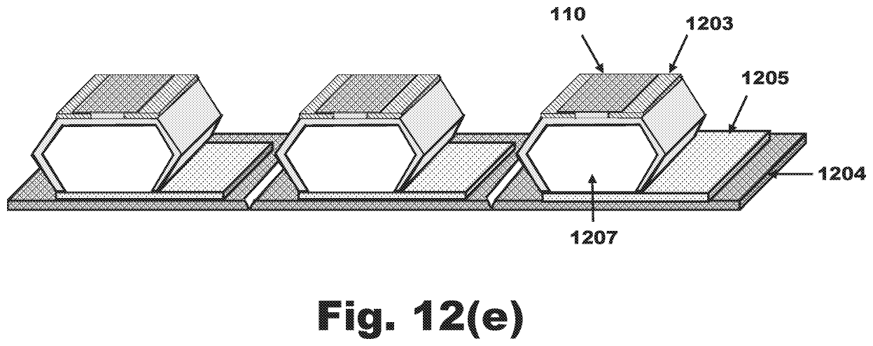

After removing the bar 112 from the substrate 101., as shown in FIG. 12(a), the bar 112 is attached to a UV-dicing tape 111 in an upside-down manner. As shown in FIG. 12(b), a metal mask 1201 can be used in disposing an n-electrode 1202 on the back side of the bar 112.

Typically, the n-electrode 1202 is comprised of the following materials: Ti, Hf, Cr, Al, Mo, W, Au. For example, the n-electrode may be comprised of Ti—Al—Pt—Au (with a thickness of 30-100-30-500 nm), but is not limited to those materials. The deposition of these materials may be performed by electron beam evaporation, sputter, thermal heat evaporation, etc.

In the case of forming the n-electrode 1202 on back side of the bar 112 after removing the bar 112 from the substrate 101, the n-electrode 1202 is preferably formed on an area on the back side of the bar 112 that is kept in good surface condition for the n-electrode 1202 to obtain a low contact resistivity.

The n-electrode 1202 also can be disposed on a top surface of the bar 112, which is the same surface made for a p-electrode.

Step 10: Breaking the Bar Into Devices

After disposing the n-electrode 1202, the bar 112 is divided into a plurality of devices 1203, as shown in FIG. 12(c), A dividing support region helps divide the bar 112 into the devices 1203.

Step 11: Mounting Each Device on a Heat Sink Plate

After Step 8, the divided bar 112 is still on the polymer film 111. In one embodiment, a UV-sensitive dicing tape can be used as the polymer film 111. In this case, the UV-sensitive dicing tape is exposed to ultra-violet (UV) light, which can reduce the adhesive strength of this tape, as shown in FIG. 12(d). This makes it easy to remove the chips from the UV-sensitive dicing tape.

In this case, a heat sink plate 1204 made of AlN is prepared. An Au—Sn solder 1205 is disposed on the heat sink plate, and the devices 1203 removed from the UV-sensitive dicing tape 111 are mounted on the heat sink plate 1204 at the Au—Sn solder 1205 between trenches 1206 in the heat sink plate 1204. At this time, the heat sink plate 1204, which is heated over the melting temperature of the solder 1205, can mount the devices 1203. The devices 1203 can be mounted in two ways—n-electrode side down or p-electrode side down. FIG. 12(e) shows the devices 1203 mounted to the heat sink plate 1204 with the n-electrode side 1204 down and the p-electrode 110 up, and facets 1207 exposed

Step 12: Coating the Facets of a Laser Device

The next step of device 1203 processing comprises coating the facets 1207. While a laser device is lasing, the light in the device that penetrates through the facets of device to the outside of the device is absorbed by non-radiative recombination centers at the facets, so that the facet temperature increases continuously. Consequently, the temperature increase can lead to catastrophic optical damage (COD) of the facet.

A facet coating can reduce the non-radiative recombination center. Preventing the COD, it is necessary to coat the facet using dielectric layers, such as AlN, AlON, Al₂O₃, SiN, SiON, SiO₂, ZrO₂, TiO₂, Ta₂O₅ and the like. Generally, the coating film is a multilayer structure comprised of the above materials. The structure and thickness of the layers is determined by a predetermined reflectivity.

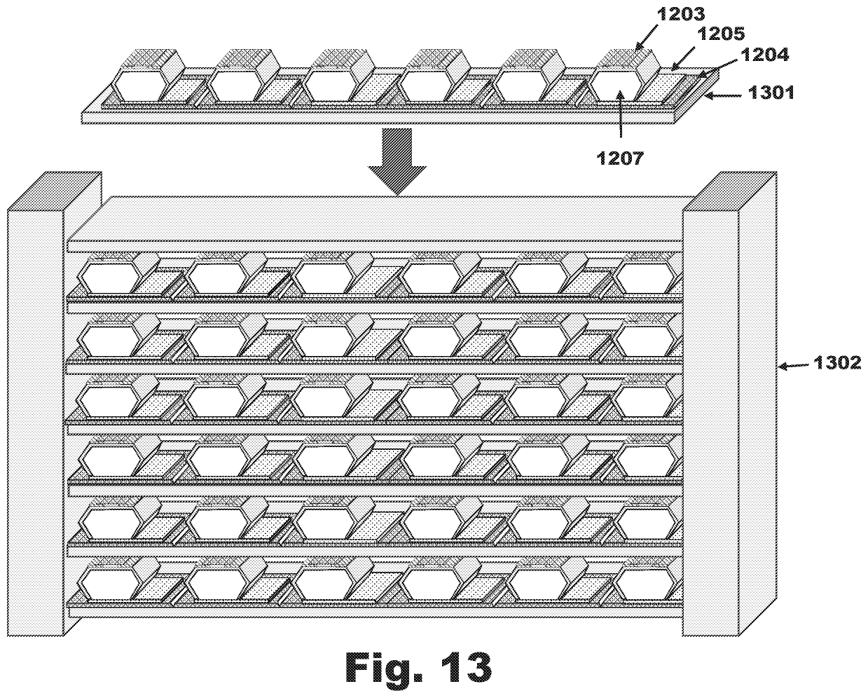

The bar 112 of device 1203 has been divided in Step 10 to obtain a cleaving facet 1207. In the results, the method of coating the facets 1207 needs to be performed on a number of devices 1203 at the same time, in an easy manner. In a facets 1207 coating process, the devices 1203 are mounted on the heat sink plate 1204 in a low horizontal position before coating, as shown in FIG. 12(e). Then, as shown in FIG. 13, the devices 1203 are mounted on a coating bar 1301, which is placed on a spacer plate, and a plurality of coating bars 1301 are stored in a coating holder 1302. Note that it is not always necessary to use a spacer plate, and the coating bar 1301 could be used alone.

By doing this, a number of devices 1203 can be coated simultaneously. In one embodiment, the facet 1207 coat is conducted at least two times: a first time for the front facet 1207 and a second time for the rear facet 1207. The length of the heat sink plate 1204 is set to be almost the cavity length of the laser diode device 1203, which makes it easy and quick to perform the coating two times. Once the coating bar 1301 is set in the coating holder 1302, both facets 1207 can be coated without setting the coating bar 1301 in the coating holder 1302 again. In one embodiment, the first coating is performed on the front facet 1207 which emits the laser light, and the second coating is performed on the rear facet 1207 which reflects the laser light. The coating holder 1301 is reversed before the second coating in the holder 1302 that deposits the coating film. This reduces the lead time of the process substantially.

Step 13: Dividing the Coating Bar

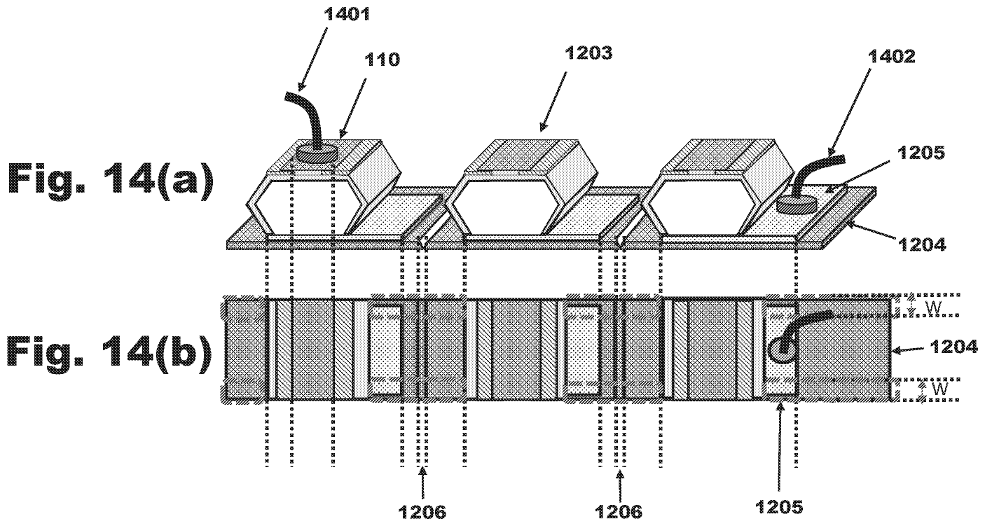

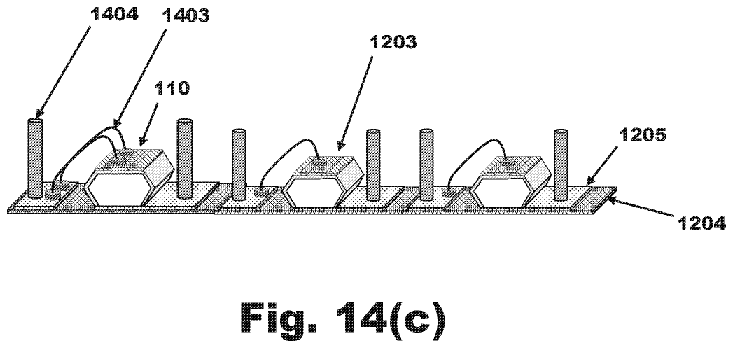

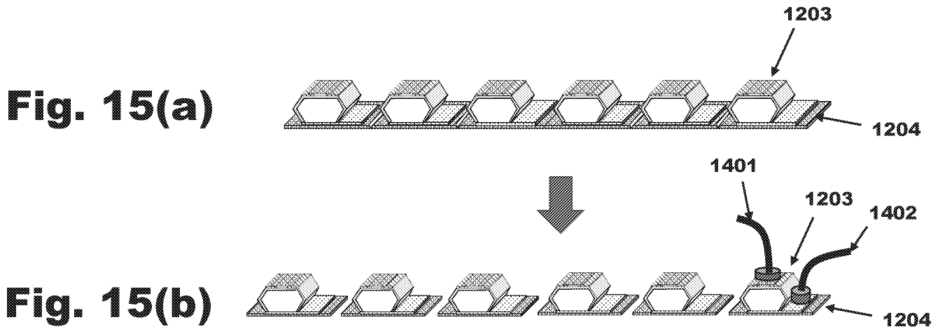

As shown in FIGS. 14(a), 14(b) and 14(c), the heat sink plate 1204 is divided at trenches 1206 formed on the surface of the heat sink plate 1204, for example, between one or more devices 1203. FIG. 15 further shows how the heat sink plate 1204 1204 is divided to separate the devices 1203. By doing this, it is easy to separate the devices 1203 after the coating process.

Step 14: Screening the Devices

This step distinguishes between defective and non-defective devices. First, various characteristics of the devices are checked under a given condition; such as output power, voltage, current, resistivity, FFP (Far Field Pattern), slope-efficiency and the like. At this point, the chips have already been mounted on the heat sink plate, so it is easy to check these characteristics. As shown in FIG. 14(a), the p-electrode 110 and the solder 1205, which has an electrical continuity to the n-electrode 1202, are contacted by wire bonds 1401, 1402 to probes. Then, non-defective devices 1203 can be selected and screened by an aging test (life time test).

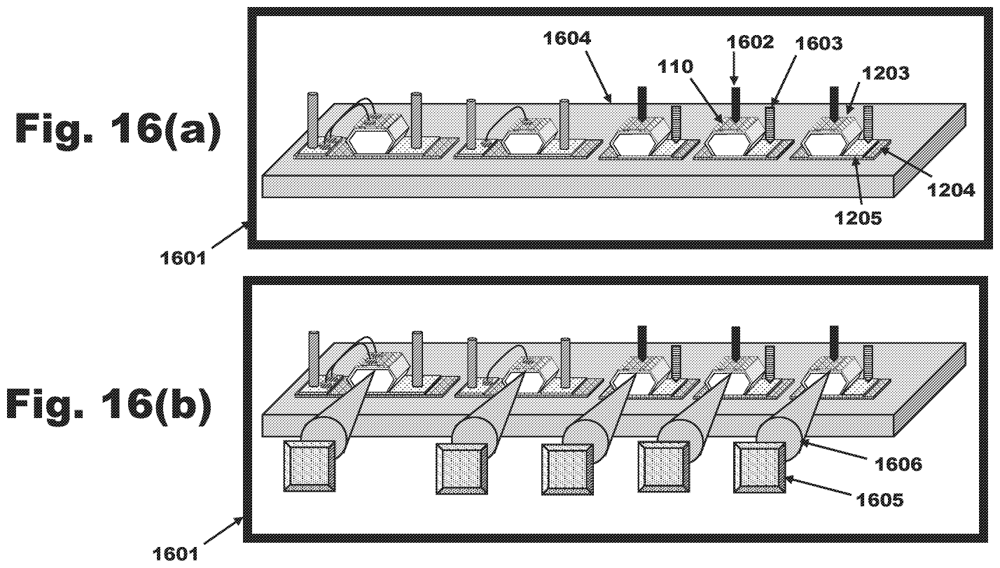

As shown in FIG. 16, it is preferable that the aging test is conducted in a box, which is sealed in dry air or a nitrogen atmosphere. A heat stage maintains the temperature of the devices with the heat sink plate during the screening test, for example, 60 degrees, 80 degrees and so on. Photodetectors are used to measure light output power, which identifies non-defective devices that have a constant output power or detects defective devices.

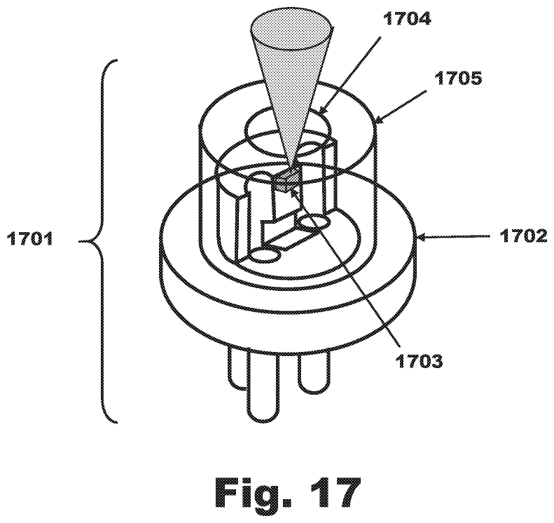

In particularly, in the case of a III-nitride laser diode device, it is known that when the laser diode is oscillated in a moisture-containing atmosphere, it deteriorates. This deterioration is caused by moisture and siloxane in the air, so the III-nitride laser diode needs to be sealed in dry air during the aging test. Consequently, when the III-nitride laser diode is shipped from a device manufacturer, the laser diode is already sealed in a dry air atmosphere by use of a TO-can package, as shown in FIG. 17.

Screening or Aging Tests

Generally speaking, the screening or aging tests are conducted before shipping, in order to screen out defective products. For example, the screening condition is conducted according to the specifications of the laser device, such as a high temperature and a high power.

Moreover, the aging test is conducted with the device mounted on/into the package, with the package sealed in dry air and/or dry nitrogen before screening, as shown in FIGS. 16(a) and 16(b). This fact makes the flexibility of packaging and mounting of the laser device restrictive.

In the prior art, if defective production happens, the defective products are discarded in the whole TO-CAN package, as shown in FIG. 17, which is a great loss for production. This makes it difficult to reduce the production costs of laser diodes. There is a need to detect defective products at an earlier step.

Advantages of the Heat Sink Plate

The heat sink plate 1204 provides a number of advantages and benefits:

Coating the facets 1207 of the device 1203 using a heat sink plate 1204, on which can be mounted a plurality of the devices 1203 in a low horizontal position and then, after the coating process, dividing the heat sink plate 1204 to separate the devices 1203 with a sub-mount using the trenches 1206, allows the device 1203 with the sub-mount to be checked in the screening test in a dry air or nitrogen atmosphere.

When doing the screening test, the devices 1203 already have two contacts, namely the p-electrode 110 and the solder 1205 on the heat sink plate 1204, or in the case of flip-chip bonding, the n-electrode 1202 and the solder 1205 on the heat sink plate 1204. Moreover, the present invention can select defective products using the screening test, when the device 1203 is only comprised of the chip and the sub-mount. Therefore, in the case of discarding the defective products, the present invention can reduce losses more than the prior art, which has great value.

As shown in FIG. 14(c), in the case of screening of high power laser diode devices, it is preferable that the heat sink plate 1204 have two parts of solder 1205 disposed without electrical continuity. One part of solder 1205 is connected to the p-electrode 110 with a wire 1403, another part of solder 1205 is connected to the n-electrode 1202. By doing this, probes 1404 for applying the current to the device 1203 can be used, which can avoid contacting the p-electrode 110 and n-electrode 1202 directly, which, in the case of applying high current for screening of a high-power laser diode, is critical. The probes 1404 do not contact directly to the electrodes 110, 1202, which could break the contacted parts, in particular in the case of applying a high current density.

Step 15: Mounting the Devices On or Into the Packages

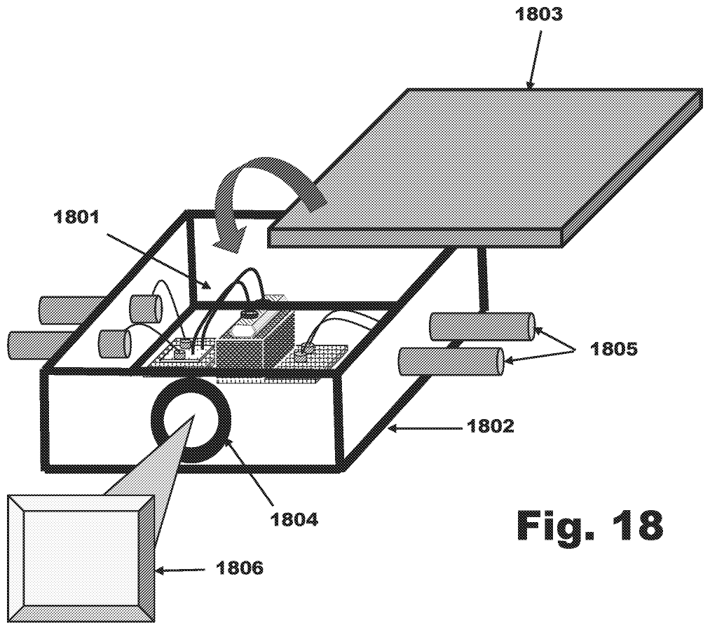

As shown in FIG. 18, the device 1801 may be mounted in a package. The solder (Au—Sn, Sn-AG-Cu and the like) or the bonding metal, which are disposed at the bottom of the package, are bonded by the wires to the solder on the heat sink plate, such as AlN, SiC and the like. The pins of the package is connected to the solder on the heat sink plate by the wires. By doing this, current from an outside supply can be applied to the devices. This is more preferable than bonding between the package and the heat sink plate, which is performed by metal bonding, such as Au—Au, Au—In, etc., bonding. This method requires a flatness at the surface of package and at the back side of the heat sink plate. However, without the solder, this configuration accomplishes a high thermal conductivity and low temperature bonding. These are big advantages for the device process.

Moreover, a phosphor can be set outside and/or inside the package, By doing this, this module can be used as a light bulb or a head light of an automobile.

As set forth herein, these processes provide improved methods for obtaining a laser diode device. In addition, once the device is removed from the substrate, the substrate can be recycled a number of times. This accomplishes the goals of eco-friendly production and low-cost modules. These devices may be utilized as lighting devices, such as light bulbs, data storage equipment, optical communications equipment, such as Li-Fi, etc.

It is difficult to package with plurality different types of lasers in one package so far. However, this method can overcome this issue due to being able to do an aging test without packaging. Therefore, in case of mounting the different types of devices in one package it can be easily to mount.

Fabricating an LED Device

In the case of fabricating an LED device, the same process may be used until Step 6. This discussion explains briefly how to make two types of LEDs. A type 1 LED has two electrodes (a p-electrode and an n-electrode) on one side of the chip, whereas a type 2 LED has an electrode on opposite sides of chip.

First, in the case of the type 1 LED, the p-electrode and n-electrode are formed in Step 6 on the top surface of the device. Then, the bars of the device remove as described in Step 8, the removed chips are mounted on packages and heat sink plates. The backside surface of the chips, the package and the heat sink plate, are bonded using an Ag paste.

Second, in the case of the type 2 LED, almost the same process is used until Step 6, where an ITO electrode is formed on the p-GaN contact layer. In this case, the method of dividing the bar is same. Moreover, it is preferable that the layer bending region is eliminated.

A Method Using Triangular Voids.

The following process is directed to a. method using triangular voids.

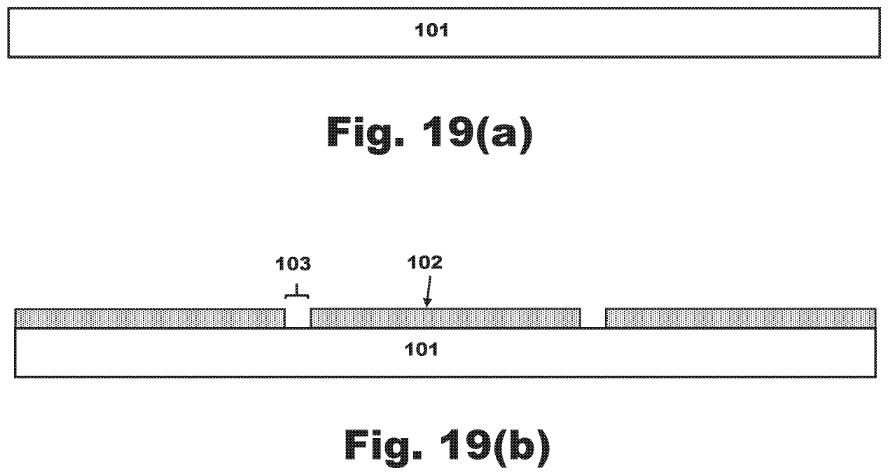

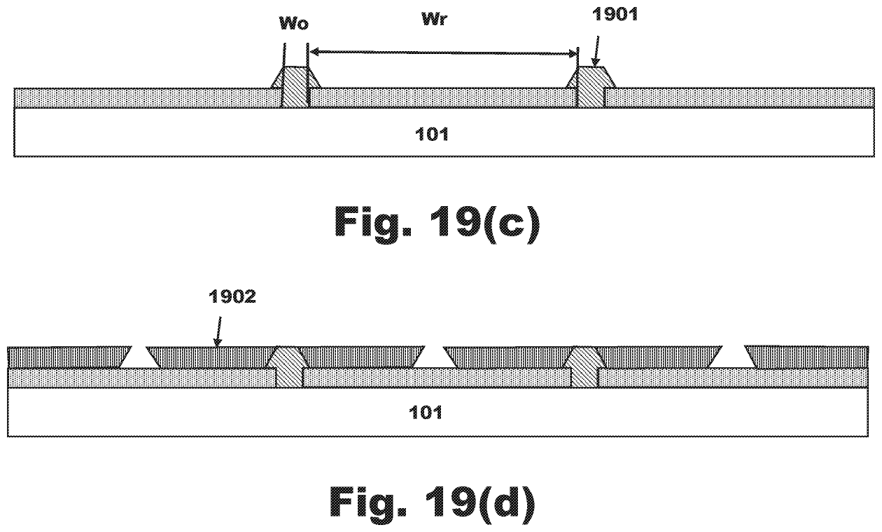

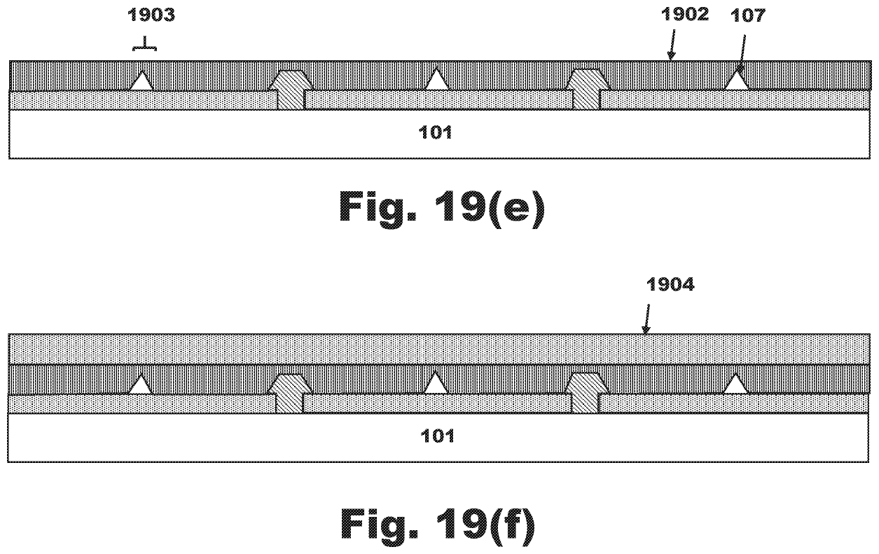

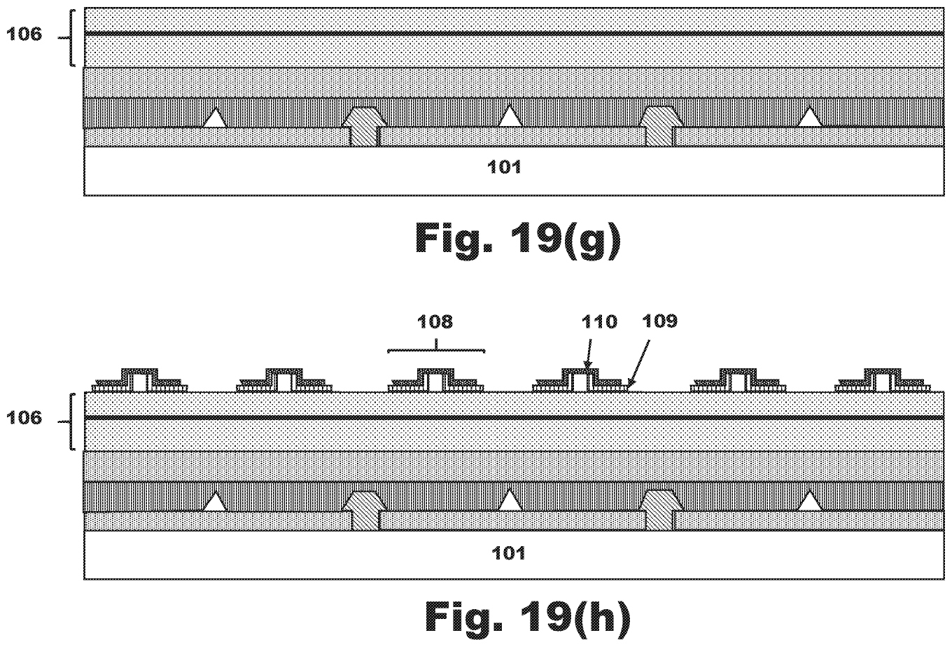

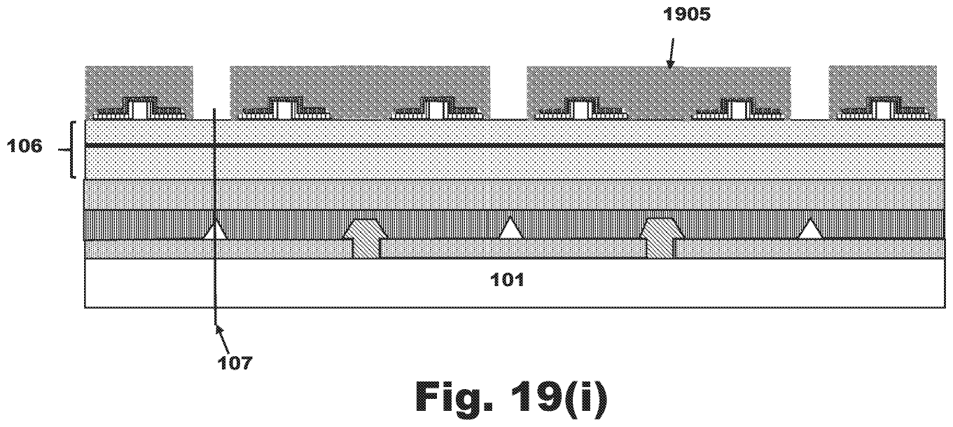

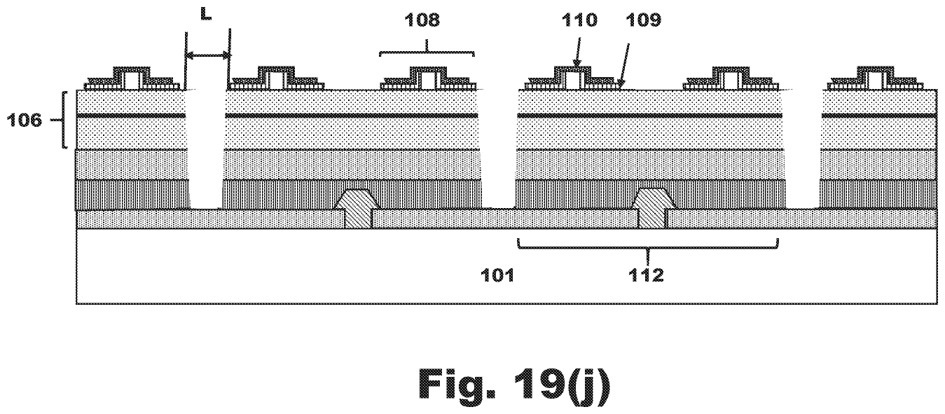

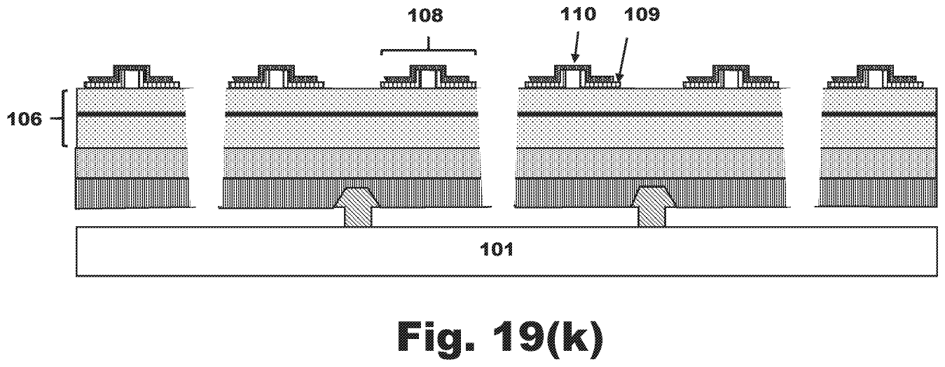

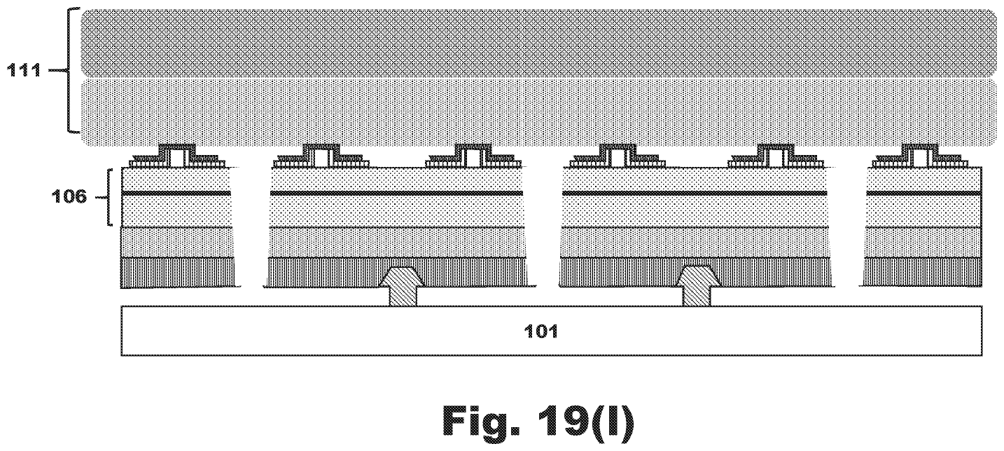

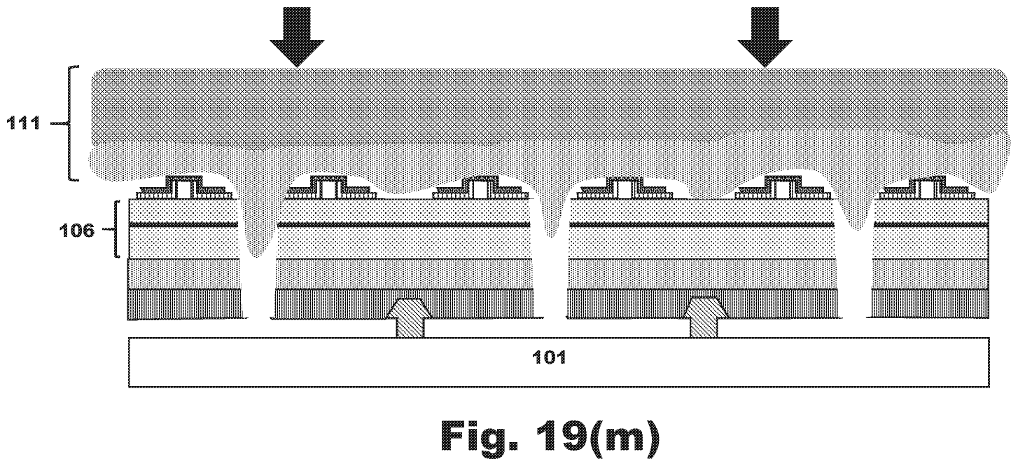

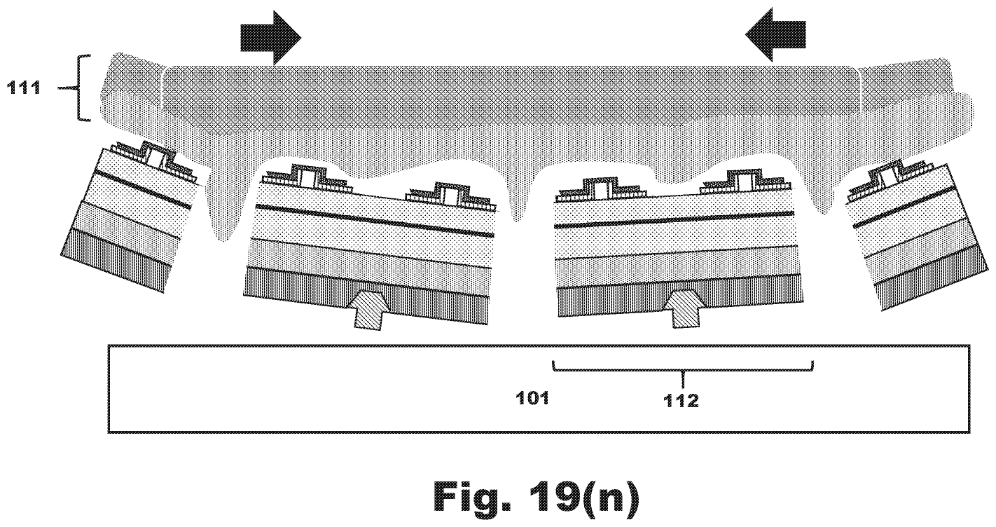

FIGS. 19(a), 19(b), 19(c), 19(d), 19(e), 19(f), 19(g), 19(h), 19(i), 19(j), 19(k), 19(l), 19(m) and 19(n) are schematics that illustrate the method using triangular voids, which is similar to the method without the growth restrict mask. However, Step 2 to Step 4 of the method of using triangular voids is different from the method without the growth restrict mask.

Step 2′: Growing the ELO III-nitride Layers on the Substrate Using the Growth Restrict Mask

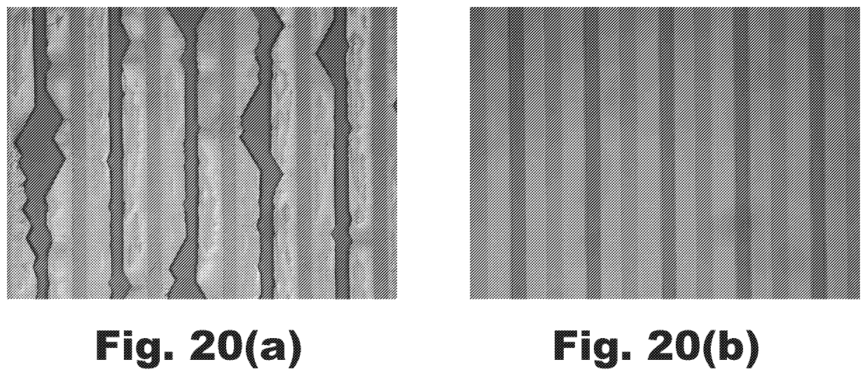

The ELO III-nitride layer 105A is initially grown 1901 on the opening area 103. It is preferable that the surface of the initial growth layer is higher than the surface of the growth restrict mask 102. When the growth condition optimizes to implement a high lateral growth rate, ELO III-nitride layers 105A growth sometimes cannot run on the growth restrict mask 102 due to the height of the growth restrict mask 102. In this case, a uniform ELO III-nitride layer 105A along the opening area 103 cannot be grown, as shown in FIG. 20(a). However, when the height of the initial growth layer is higher than the height of the growth restrict mask 102, uniformity of the ELO III-nitride layer 105A can be grown as shown in FIG. 20(b).

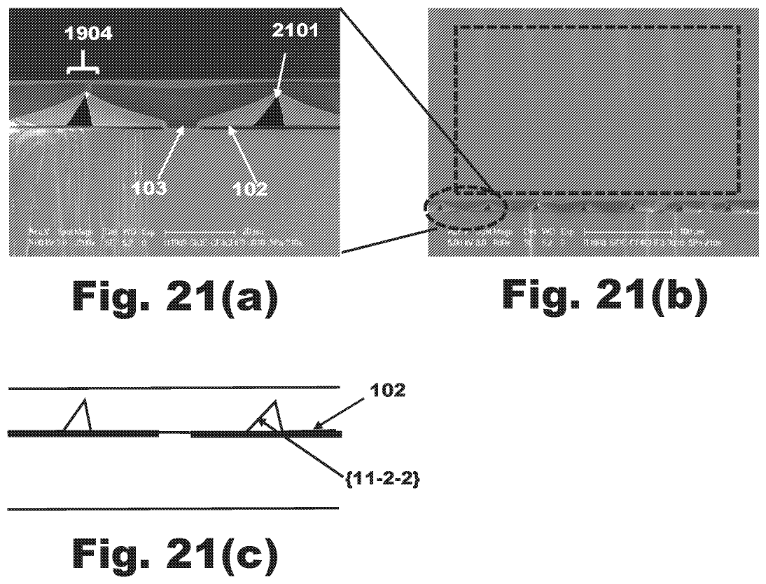

ELO III-nitride layers 1902 are grown from the initial layer 1901. Low V/III growth condition accelerates the growth rate of the lateral direction, which helps to form an inverted taper facet. This inverted taper facet is {11-2-2} as shown in FIGS. 21(a), 21(b) and 21(c). During the growth of the ELO III-nitride layer, {11-2-2} facet appears, but just before coalescence, {11-2-2} facet is inclined due to the growth condition change which is caused by closing to each ELO III-nitride layer 105A, However, the inverted taper facets help to create triangular voids 2101 in the ELO III-nitride layers 105A as shown in FIGS. 21(a) and 21(b). FIGS. 21(a) and 21(b) are cross-sectional and birds-eye view SEM images of the ELO III-nitride layer 105A after the coalescence, respectively. Once the ELO III-nitride layers 105A coalesce in this situation, triangular voids will not disappear even though the growth continues.

MOCVD is used for the epitaxial growth of the ELO III-nitride layer 1902. Trimethylgallium (TMGa) is used as the IIII elements source; ammonia (NH₃) is used as the raw gas to supply nitrogen; and hydrogen (H₂) and nitrogen (N₂) are used as a carrier gas of the III elements sources. It is important to include hydrogen in the carrier gas to obtain a smooth surface to the epilayers. The thickness of the ELO III-nitride layer 105A is about 1 μm-10 μm. The ELO III-nitride layer 1902 may comprise a GaN or AlGaN, InGaN, InAlGaN layer in order to obtain a smooth surface.

Triangular voids 107 can effectively release the stress from the difference of the thermal expansion coefficient between the III-nitride layers 105A, 105B, 106 and the growth restrict mask 102. Voids 107 made by doing this occur directly on the growth restrict mask 102 and are surrounded by the growth restrict mask 102 and the ELO III-nitride layers 105A, which can effectively release the stress from the growth restrict mask 102. Moreover, the triangular shape of the voids 107 is much preferable in terms of releasing the stress because of the height of the voids 107 are higher than the voids 107 made without the growth restrict mask 102. In an additional advantage, the voids 107 can form without growth interruption.

After coalescing, those voids 107 prevent the occurrence of cracks in the ELO III-nitride layers 105A. Moreover, the ELO III-nitride layer 105A substantially covers the growth restrict mask 102, which prevents p-type layers from being compensated by decomposition of the growth restrict mask 102.

Step 3: Flatting the Surface Above the Void

Just after the coalescence of the ELO III-nitride layers 105A, the above portion of the voids 107 which is depressed 1903, its depth is over 100 nm. To flatten the surface, it is preferable to grow a flattening layer 1904 on the ELO III-nitride layers 1902. The thickness of the flattening layer 1904 is at least 1 μm, and more preferably over 2 μm, for improving the flatness of the epilayer surface. If the depressed portion 1903 cannot he flat before the growth of the III-nitride device layers 106, this sometimes causes a fluctuation of the In, Al, etc., composition at or near the depressed portion 1903. The depth of the depressed portion 1903 preferably is up to 50 μm, and more preferably less than 30 μm. To flatten the surface, the flattening layer 1904 is grown. This layer 1904 is an unintentionally doped (UID) layer or Si-doped layer. In addition, an Mg-doped layer or a layer 301 co-doped with Mg and Si can be used as the 111-nitride layer. The growth of doping Mg is efficient to bury the depressed portion 1903. Moreover, there are no problems when implementing polishing the surface of the flattening layer 1904 for the sake of obtaining a further flat surface.

Step 4: Growing III-nitride Device Layers on the Flatting Layer

As shown in FIG. 19(g), the III-nitride device layers 106 are grown on the flattening layer 1904 continuously. The III-nitride device layers 106 are generally grown at temperature ranges from 700 to 1250° C. For example, the growth parameters include the following: TMG is 12 sccm, NH₃ is 8 slm, carrier gas is 3 slm, SiH₄ is 1.0 sccm, and the V/III ratio is about 7700. These growth conditions are only one example, and the conditions can be changed and optimized for each of above described layers.

After conducting Step 4, this method performs Step 6 as set forth above and then performs the following Step 7.

Step 7: Etching the III-nitride Device Semiconductor Layer, the Flatting Layer, and the ELO III-nitride Layer

The etching of the III-nitride device layers 106, the flattening layer 1904, and the ELO III-nitride layer 1902 can be performed by a conventional photo-lithography and dry etch method, as shown in FIGS. 19(i) and 19(j). A photoresist 1905 is patterned to etch the above portion of the voids 107, although other materials can be used as well.

The depth of the etching is at least to the top of the void region 107 exposed by this etching. By doing this, the epilayer can be divided like bars 112. To facilitate removing the bars 112, the growth restrict mask 102 is removed by wet etching as shown in FIG. 19(k).

After dissolving the growth restrict mask 102, the processing of the bars 112 is the same as Step 8 above, as shown in FIGS. 19(l), 19(m), 19(n).

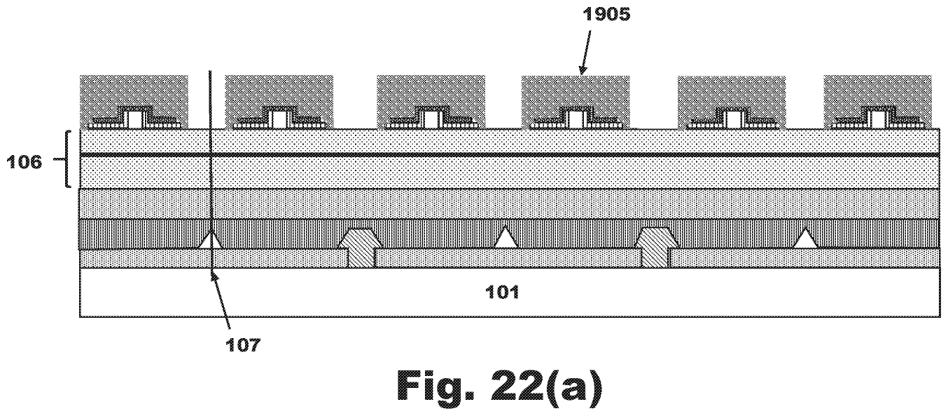

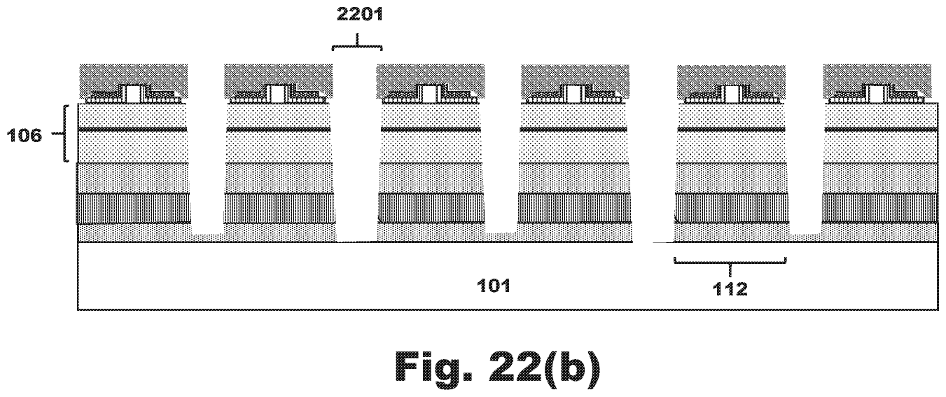

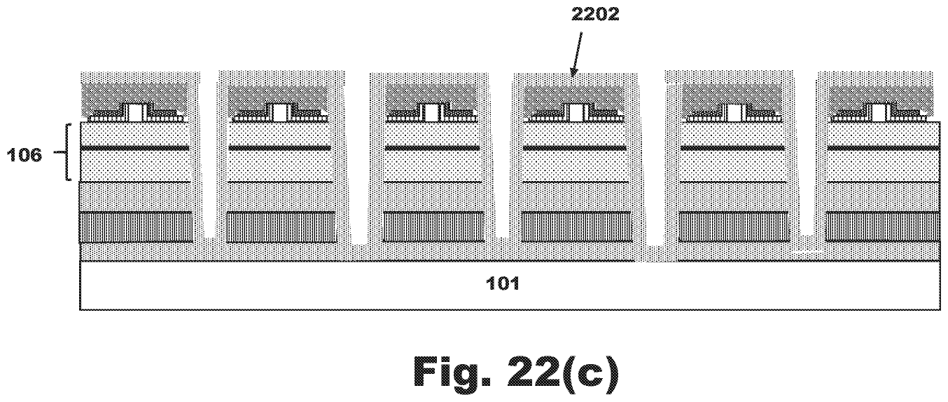

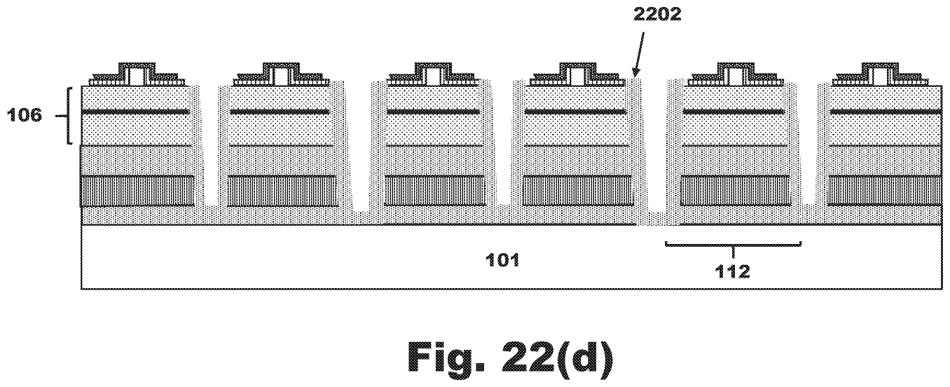

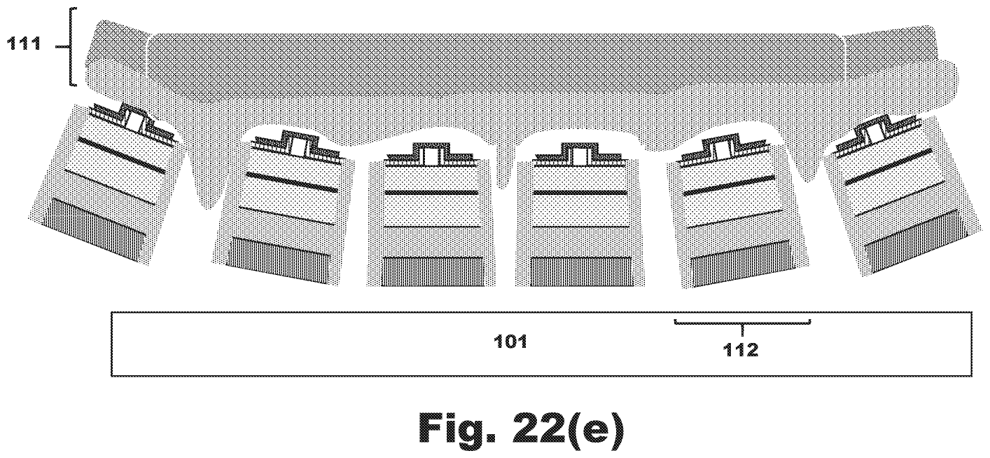

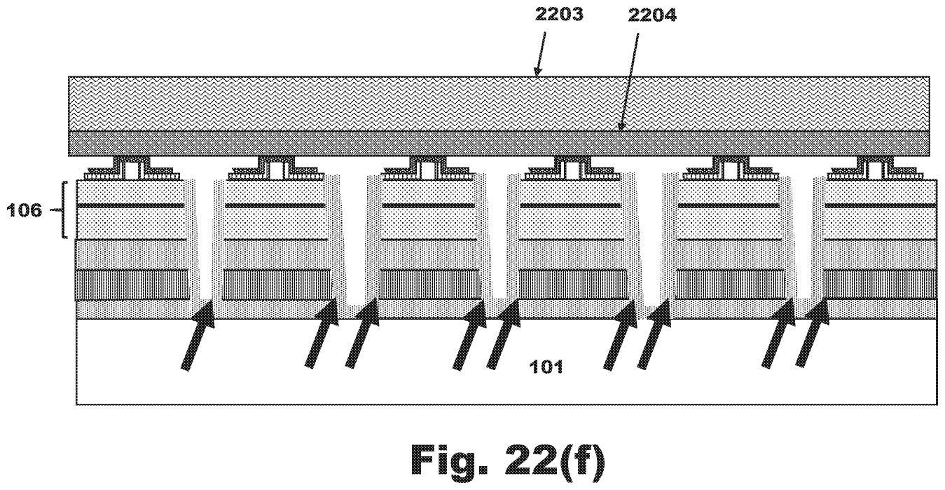

It is possible to remove the bars using the process as shown in FIGS. 22(a), 22(b), 22(c), 22(d), 22(e) and 22(f), which are schematics that illustrate an alternative to FIGS. 19(j), 19(k), 19(l), 19(m) and 19(n). in this process, both the upper part of the voids 107 and the upper part of the opening area 102 are eliminated by etching. As shown in FIGS. 22(a) and 22(b), these can be etched by a dry etching process. In this time, if etching region at the opening area 2201 reaches the growth restrict mask 102, the bars 112 can be separated from the substrate 101. A hooking layer 2202, such as SiO₂, etc., is deposited on the substrate 101 as shown in FIG. 22(c). Dissolving the photoresist 1905 can make the hooking layer 2202 on the photoresist is lifted off, as shown in FIG. 22(d).

This hooking layer 2202 has two purposes. One is to fix the bar 112 on the growth restrict mask 102 temporarily for the sake of avoiding peeling off the bar 112 during dissolving the photoresist by solvent with ultra-sonic. Second, using dielectric materials as a hooking layer 2202 can passivate the side facet of the bar 112. The side facet of the bar 112 sometimes has a damage from the dry etching depending on the etching condition. If the bar 112 width is narrow, leakage current occurs at the side facet of the bar due to etching damage, which might affect the characteristics of the devices. The material can be chosen to reduce leakage current at the side facet, for example, SiO₂, SiON, SiN, Al₂O₃, AlON, AlN, ZrO₂, Ta₂O₃, etc.

The strength of fixing can be varied by changing the thickness of the hooking layer 2202. It can be controlled the strength not to remove the bar 112 during an ultra-sonic or a post-process etc.

It can be removed using Step 8 before mentioned as shown in FIG. 22(e). It is possible to remove in a different way as shown in FIG. 22(f). This way is to use a supporting plate 2203 with solder 2204. Using the solder 2204 on the supporting plate 2203 can be bonded with the bars 112. A conventional bonding method can be used as well. Generally, bonding processes increase the temperature during bonding process. If an Au—Sn solder is used, the bonding temperature is about around 280° C. After bonding, when temperature goes down to the room temperature the thermal stress from a different thermal expansion coefficient can break the hooking layer 2202.

Since the bonding strength at the interface the ELO III-nitride layer 1902 and the growth restrict mask 102 is not strong, the bar 112 can be easily separated from the substrate 101 for removal. Moreover, ultrasonic processes can be used to break the hooking layer 2202. In this case, the breakpoint of the hooking layer 202 is shown in FIG. 22(f) marked with arrows.

By doing this, the bar 112 can be removed from the substrate 101. Until the packaging process, it can be the same process as without the growth restrict mask 102.

Definitions of Terms

III-nitride-Based Substrate

As long as a ITT-nitride-based substrate 101 enables growth of a III-nitride-based semiconductor layer through a growth restrict mask 102, any GaN substrate that is sliced on a {0001}, {11-22}, {1-100}, {20-21}, {20-2-1}, {10-11}, {10-1-1} plane, etc., or other plane, from a bulk GaN and AlN crystal can be used.

Hetero-Substrate

Moreover, the present invention can also use a hetero-substrate 101 for the device. For example, a GaN template or other III-nitride-based semiconductor layer may be grown on a hetero-substrate 101, such as sapphire, Si, GaAs, SiC, etc., for use in the present invention. The GaN template or other III-nitride-based semiconductor layer is typically grown on the hetero-substrate 101 to a thickness of about 2-6 μm, and then the growth restrict mask 102 is disposed on the GaN template or the other III-nitride-based semiconductor layer. The growth restrict mask is formed directly on the hetero-substrate such as sapphire, silicon, and SiC as another option. In this case, the initial growth layer or the ELO III-nitride layer 105A is directly grown on this hetero-substrate with the growth restrict mask. Thus, the substrate is not necessary to have a GaN layer.

Growth Restrict Mask

The growth restrict mask 102 comprises a dielectric layer, such as SiO₂, SiN, SiON, Al₂O₃, AlN, AlON, MgF, ZrO₂, etc., or a refractory metal or precious metal, such as W, Mo, Ta, Nb, Rh, Ir, Ru, Os, Pt, etc. The growth restrict mask 102 may be a laminate structure selected from the above materials. It may also be a multiple-stacking layer structure chosen from the above materials.

The growth restrict mask 102 is deposited by sputter, electron beam evaporation, plasma-enhanced chemical vaper deposition (PECVD), ion beam deposition (IBD), etc., but is not limited to those methods.

The thickness of the growth restrict mask 102 is about 0.05-3 μm. The width of the mask 102 is preferably larger than 20 μm, and more preferably, the width is larger than 40 μm. The length of the opening area 103 is, for example, 200 to 35000 μm; the width is, for example, 2 to 180 μm.

In one embodiment, the growth restrict mask 102 is formed with a 1 μm-thick SiO₂ film, wherein the length of the opening area 103 is 1200 μm; the width is 15-25 μm; the intervals of the opening areas 103 are 55-85 μm; and the width of the mask 102 portion is 40-60 μm.

Direction of the Growth Restrict Mask

On an c-plane free standing GaN substrate 101, the striped opening areas 103 are arranged in a first direction parallel to a 11-20 direction (a-axis) of the substrate 101 and a second direction parallel to a 1-100 direction (m-axis) of the substrate, periodically at a first interval and a second interval, respectively, and extend in the second direction.

On a m-plane free standing GaN substrate 101, the striped opening areas 103 are arranged in a first direction parallel to a 11-20 direction (a-axis) of the substrate 101 and a second direction parallel to a 0001 direction (c-axis) of the substrate 101, periodically at a first interval and a second interval, respectively, and extend in the second direction.

On a semipolar (20-21) or (20-2-1) GaN substrate 101, the opening areas 103 are arranged in a direction parallel to [−1014] and [10-14], respectively.

Alternatively, a hetero-substrate 101 can be used. When a c-plane GaN template is grown on a c-plane sapphire substrate 101, the opening area 103 is in the same direction as the c-plane free-standing GaN substrate 101; when an m-plane GaN template is grown on an m-plane sapphire substrate 101, the opening area is same direction as the m-plane free-standing GaN substrate 101. By doing this, an m-plane cleaving plane can be used for dividing the bar 112 of the device with the c-plane GaN template, and a c-plane cleaving plane can be used for dividing the bar 112 of the device with the m-plane GaN template; which is much preferable.

The width of the opening are 103 is typically constant n the second direction, but may be changed in the second direction as necessary.

Growth Support Layer.

A growth support (GS) layer may be used with a substrate 101. The growth support layer can be any semiconductor alloy layer, any dielectric layer and any insulate layer which supports a growth of a III-nitride layer on top of the growth support layer.

Sonic potential candidates for growth support layers include AlN, CrN, BN, GaN, ZnO, Ga₂O₃, etc., but is not limited to these materials. A typical thickness of a growth support layer is around 10 nm-1000 nm. Once the growth support layer is placed on the growth restrict mask 102 regions or replaces a dielectric layer, then the entire semiconducting substrate 101 can be capable of growing III-nitride layers without need of a growth interruption.

III-nitride-Based Semiconductor Layers

The ELO III-nitride layer 105A and the III-nitride device layers 106 are shown in FIGS. 1(a)-1(k), and comprise III-nitride-based semiconductor layers. These layers can include In, Al and/or B, as well as other impurities, such as Mg, Si, Zn, O, C, H, etc.

The III-nitride device layers 106 generally comprise more than two layers, including at least one layer among an n-type layer, an undoped layer and a p-type layer. The III-nitride device layers 106 specifically comprise a GaN layer, an AlGaN layer, an AlGaInN layer, an InGaN layer, etc.

Semiconductor Device

The semiconductor device is, for example, a Schottky diode, a light-emitting diode, a laser diode, a photodiode, a transistor, etc., but is not limited to these devices. This invention is particularly useful for micro-LEDs and laser diodes, such as edge-emitting lasers and vertical cavity surface-emitting lasers (VCSELs). This invention is especially useful for a semiconductor laser which has cleaved facets. In the semiconductor device, a number of electrodes according to the types of the semiconductor device are disposed at predetermined positions.

The Area of Forming a Device

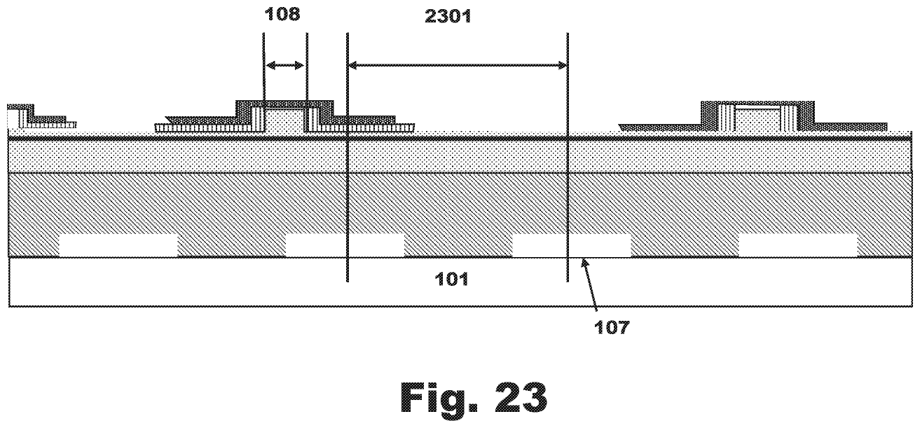

In the present invention, the area 2301 for forming a device preferably avoids the center of the void region 107, as shown in FIG. 23. This area includes a high density of dislocations, because the coalescence of the ELO III-nitride layer 105A occurs at the center of the void region 107. It is much preferable that the device be formed in an area about 5 μm away from the center of the void region 107. In the case of a laser diode device, the ridge of the laser structure is preferably located at the area for forming the device.

Polymer Film

A polymer film 111 is used in order to remove the III-nitride device layers 106, regrowth layer 105B and ELO III-nitride layer 105A from the substrate 101.

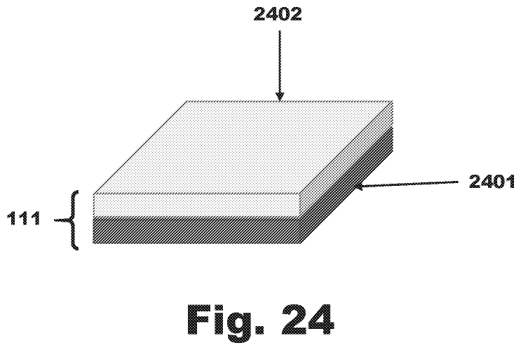

In the present invention, dicing tape, including UV-sensitive dicing tape, which are commercially sold, can be used as the polymer film 111. For example, the structure of the polymer film 111 may comprise double layers 2410, 2402 as shown in in FIG. 24, or triple layers, but is not limited to those examples. The base film material 2401, for example, having a thickness of about 115 μm, may be made of polyvinyl chloride (PVC). An adhesive layer 2402, for example, having a thickness of about 40 μm, may be made of acrylic UV-sensitive adhesive.

When the UV-sensitive dicing tape is exposed the UV light, the stickiness of the tape is drastically reduced. After removing the bars 112 from the substrate 101, the UV-sensitive dicing tape is exposed by the UV light, which makes it is easy to remove.

Heat Sink Plate

The removed bar 112 is transferred to a heat sink plate 1204, which may be AlN, SiC, Si, Cu, CuW, and the like, As shown in FIG. 12(d), the solder 1205 for bonding, which may be Au—Sn, Su—Ag—Cu, Ag paste, and the like, is disposed on the heat sink plate 1204. Then, an n-electrode 1202 or p-electrode 110 is bonded to the solder 1205. The devices 1203 can also be flip-chip bonded.

In the case of bonding LEDs to the heat sink plate 1204, the size of the heat sink plate 1204 does not matter, and it can be designed as desired.

In the case of bonding LDs to the heat sink plate 1204, it is preferable that the length of the heat sink plate 1204 be the same or shorter than the length of the LD for the facets 1207 coating process, wherein the length of the LDs is almost the same as the length of the laser cavity. By doing this, it is easy to coat both facets 1207 of laser cavity. If the length of the heat sink plate 1204 is longer than laser cavity, then the heat sink plate 1204 may prevent uniform coating of the facets 1207.

Long Width Heat Sink Plate

A long width for the heat sink plate 1204 makes the process of fabricating the laser device more productive. As shown in FIG. 13, the heat sink plate 1204 is placed on the coating bar 1301, and then stacked with other coating bars 1301 in the coating holder 1302 for coating the facets 1207 a plurality of the devices 1203 at the same time. Consequently, a single coating process can coat a lot of devices 1203.

Heat Sink Plate with Trenches

It is preferable that the heat sink plate 1204 have trenches 1206 for dividing the devices 1203, as shown in FIG. 12(d). This structure is useful after the facet 1207 coating process, where the heat sink plate 1204 is divided into one or more devices 1203, for example, single devices 1203 or an array of devices 1203. After dividing the heat sink plate 1204, the devices 1203 can be fabricated into modules, such as lighting modules. The trenches 1206 in the heat sink plate 1204 guide the division into the devices 1203. The trenches 1206 can be formed by a wet etching method and mechanically processed before the devices 1203 are mounted. For example, if the heat sink plate 1204 is made of silicon, wet etching can be used to form the trenches 1206. Using the trenches 1206 in this manner, reduces the lead time of the process.

Heat Sink Plate with Solder

It is preferable that the length of solder 1205 be shorter than the device 1203 length on the heat sink plate 1204, as shown in FIG. 12(e). This prevents any wraparound of the solder 1205 to the facets 1207, which could cause a deterioration of the device 1203 characteristics. In particular, wraparound should be avoided for flip-chip mounting.

As shown in FIGS. 14(a) and 14(b), after the coating process, the heat sink plate 1204 bar has wraparound areas, which are the areas surrounded by the dashed lines. The wraparound area has a width W of about 10-20 μm. The coating film will have coated these areas. It is also difficult to avoid coating the solder 1205 with the coating film. Generally, the coating film is selected from one or more dielectric materials, which is why this area does not have conductivity. This is a problem for both conductivity and adhesiveness when a wire is bonded to the solder 1205. Therefore, it is preferable that the wire be placed to avoid the wraparound area. At least, the place of wire bonding should be about 25 μm away from the edge of the heat sink plate 1204.

### Alternative Embodiments

### First Embodiment

An III-nitride-based semiconductor device and a method for manufacturing thereof, according to a first embodiment are explained. The process of the device has described as set forth above fundamentally.

In the first embodiment, as shown in FIGS. 1(a)-1(b), a substrate 101 is first provided, and a growth restrict mask 102 that has a plurality of striped openings areas 103 is formed on the substrate 101.

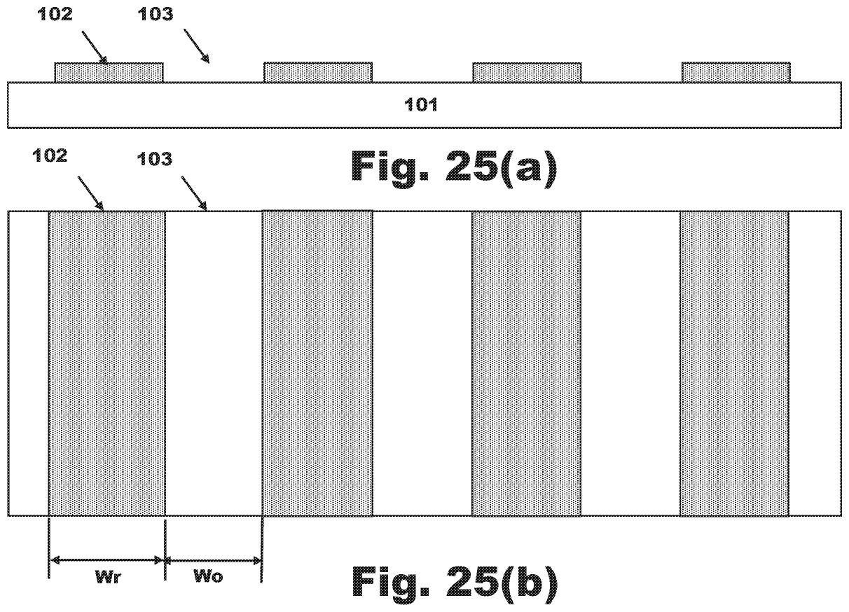

In this embodiment, the substrate 101 is a c-plane substrate made of III-nitride-based semiconductor, which has a mis-cut orientation with −0.4 degree towards the m-axis. In this embodiment, as shown in FIG. 9(f) and FIGS. 25(a) and 25(b), the opening area 103 width Wo and the growth restrict mask 102 width Wr are set to 10 μm and 10 μm, respectively. The thickness of the growth restrict mask 102 is 0.22 μm, and the width of etching area L is 20 μm.

In the present embodiment, the process is shown in FIGS. 1(a)-1(e). As shown in FIG. 5(b), the present invention achieved to flatten the surface without cracks after the growth of the regrowth layer 105B in the situation of including the void regions 107. Afterwards, it removes the bar 112 using the method described in FIGS. 1(f), 1(g), 1(h), 1(i), 1(i) and 1(k).

### Second Embodiment

In a second embodiment, the substrate 101 is a c-plane substrate made of III-nitride-based semiconductor, which has a mis-cut orientation with −0.2 degree towards the in-axis. In this embodiment, the opening area 103 width Wo and the growth restrict mask 102 width Wr are set to 25 μm and 55 μm, respectively. The thickness of the growth restrict mask 102 is 1.0 μm. The width of etching area L is 20 μm. By doing this, it can obtain a bigger size bar 112. In this case, the bar 112 includes one void region 107, which renders it easy to remove.

### Third Embodiment

In a third embodiment, a different type of the regrowth layer 105B can be used. In the first embodiment, an unintentionally doped layer or Si-doped layer was used as the regrowth layer 105B. In the third embodiment, an Mg-doped layer 601 is used as a regrowth layer 105B, as shown in FIGS. 6(a) and 6(b), which are variants of FIGS. 1(d) and 1(e). This regrowth layer 105B can effectively bury the depressed region at the no-growth region 104.

However, it is possible to disappear the void region 107 depending on the growth conditions and the dimensions of the growth restrict mask 102, as shown in FIG. 8. in this case, the size of the void region 107 is smaller than a pre-determined size, and the regrowth layer 10513 buries the void region 107. It has been found that a regrowth layer 105B that is an Mg-doped layer or a co-doped Mg and Si layer has this effect when the void region 107 remains after the growth of regrowth layer 105B. In this regard, it is preferable that the regrowth layer 105B contains an Mg dopant.

There is another advantage to using an Mg-doped regrowth layer 105B, in that it can reduce the number of holes. The existence of holes results in a roughness at the surface of the layers, which makes it important to reduce the number of holes. Moreover, an Mg-doped regrowth layer 105B can bury a depressed portion at the no-growth region 104, and can reduce the growth time of the regrowth layer 105B.

### Fourth Embodiment

In a fourth embodiment, after the growth of the regrowth layer 105B, the surface of the regrowth layer 105B is polished in order to level the surface, as shown in FIGS. 3(a) and 3(b), which are variants of FIG. 1(e). Another version is shown in FIGS. 9(a), 9(b), 9(c), 9(d), 9(e) and 9(f), which are variants of FIGS. 1(d), 1(e), 1(e), 1(f), 1(g) and 1(h), respectively, where an Mg-doped layer 601 is used as a regrowth layer 105B.

This reduces the in-plane distribution of the thickness of the layers. Fluctuations in the characteristics of devices also improve, which increases the yield during mass-production. Moreover, in case of using an Mg-doped layer as the regrowth layer 105B, polishing the Mg-doped regrowth layer 10513 eliminates the need for the ELO III-nitride layer 105A to be an Mg-doped layer. The existence of Mg-doped layers leads to an increase in the voltage of the device. Therefore, polishing results in a decrease in voltage. Using the co-dope layer as a regrowth layer 105B also improve the voltage of the device.

### Fifth Embodiment

In a fifth embodiment, the device has multiple void regions 107 before the removal of the device, as shown in FIG. 23. By doing this, a large chip size for device can be obtained.

### Sixth Embodiment

In a sixth embodiment, the ELO III-nitride layer 105A can be grown by hydride vapor phase epitaxy (HVPE), which can grow III-nitride layers with a high growth rate. In this case, using HVPE to grow the ELO III-nitride layer 105A makes it possible to reduce the growth time while covering a wider are of the growth restrict mask 102 with the ELO III-nitride layer 105A.

The present invention can make other devices using the ELO technique, such as an AlGaAs laser diode, etc. It can also be adapted to make a LED device.

### Seventh Embodiment

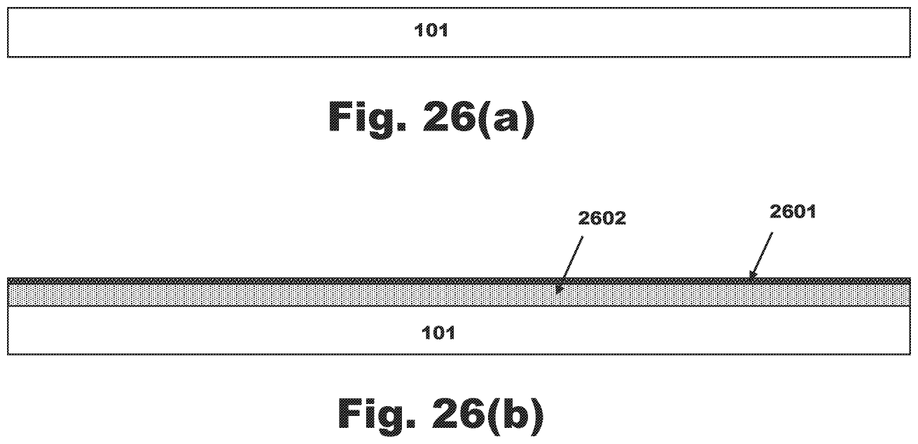

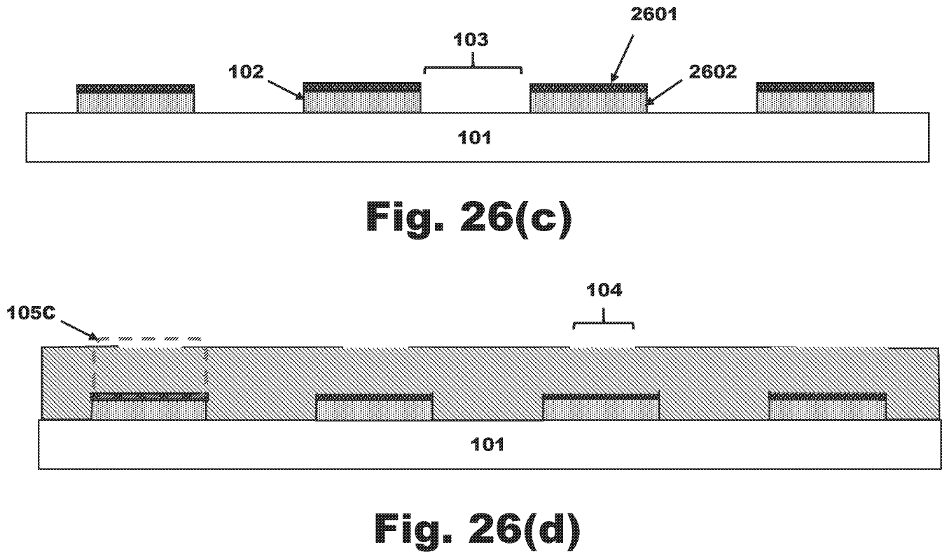

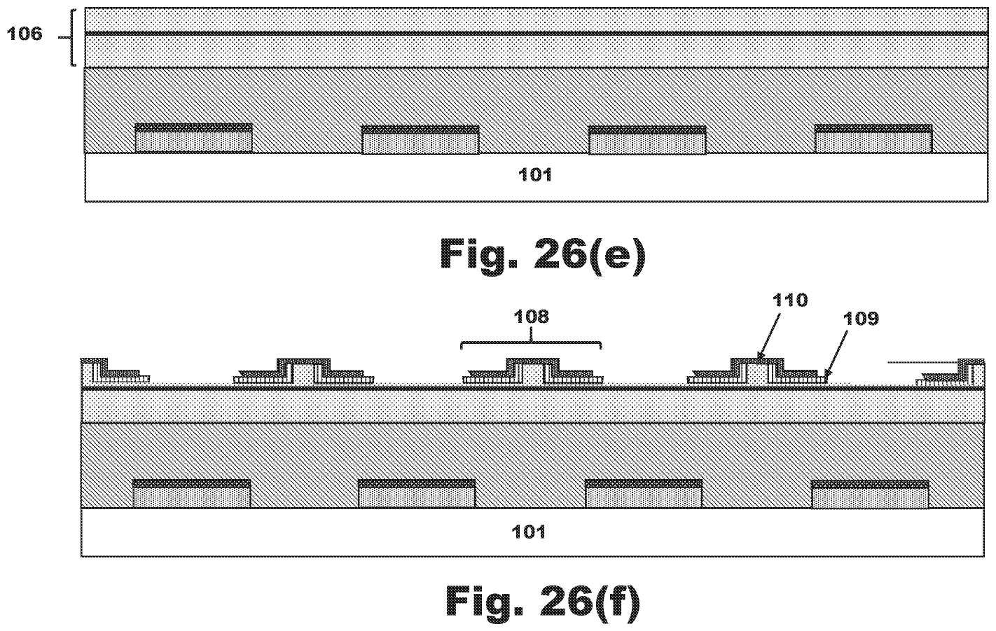

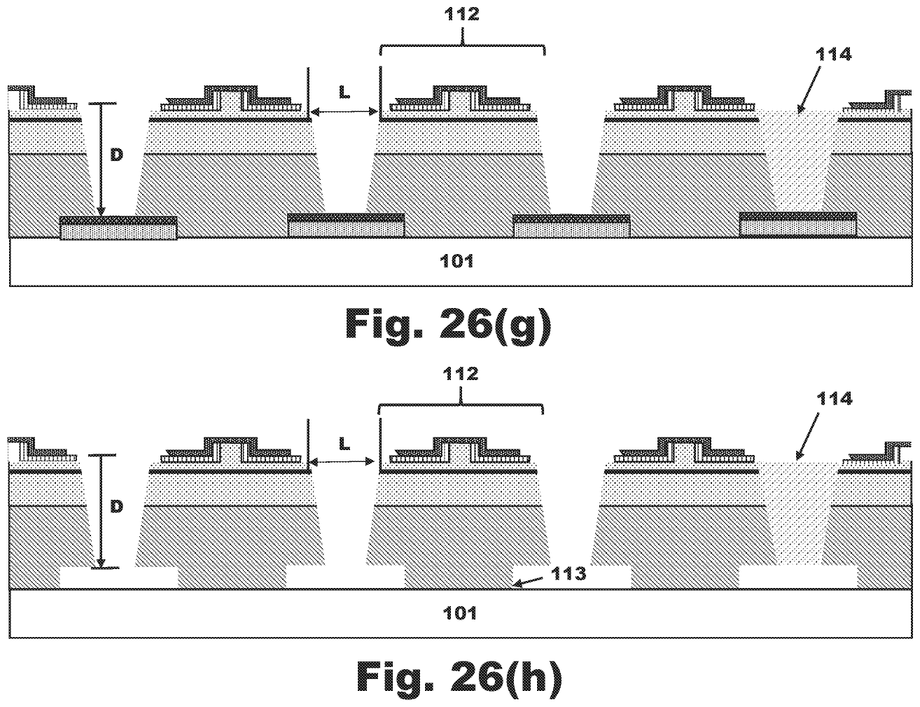

A III-nitride-based semiconductor device and a method for manufacturing thereof using a growth support layer deposited on the substrate, according to a seventh embodiment as illustrated by FIGS. 26(a), 26(b), 26(c), 26(d), 26(e), 26(f), 26(g) and 26(h).

This embodiment uses a growth support layer 2601 deposited on the substrate 101. The primary advantage with a growth support layer 2601 is that it takes a short time to cover a whole substrate 101 or wafer with a III-nitride layer. For example, using a wide growth restrict mask 102, e.g., over 100 μm wide, takes a long time to cover the growth restrict mask 102, due to the use of the lateral growth technique. In this embodiment, since a III-nitride layer can grow on the growth support layer 2601, the time to cover the growth support layer 2601 with a III-nitride layer is short. The time is the same not depending on the width of the growth support layer 2601. Thus, there is a big advantage when a wide width growth support layer 2601 is used, which can form a wide bar 112 easily.

Two different methods are described to realize flattened epilayers on a III-nitride base substrate 101 using growth support layers 2601. In the first method, a dielectric layer 2602 is deposited on a semiconductor substrate 101 followed by the growth support layer 2601. The dielectric layer 2602 thickness can be anywhere between 100 nm to 1000 nm, and growth support layer 2601 thickness can be anywhere between 10 nm to 100 nm. Typical examples of dielectric layers 2602 are SiO₂, SiN, SiON, or a mixture thereof, and typical examples for growth support layers 2601 are AlN, AlON, BN, CrN, ZnO, etc. The dielectric layer 2602 and growth support layer 2601 are then patterned to have a plurality of striped openings 103 similar to those shown for the growth restrict mask 102 in FIG. 1(b). The etching of the dielectric layer 2602 and the growth support layer 2601 can be performed chemically using a BHF solution followed a suitable solvent for the growth support layer 2601. For example, AlN can be dissolved using a heated KOH (potassium hydroxide) solution. By doing so, one can obtain a void under the flattened epilayer regions at the patterned portions.

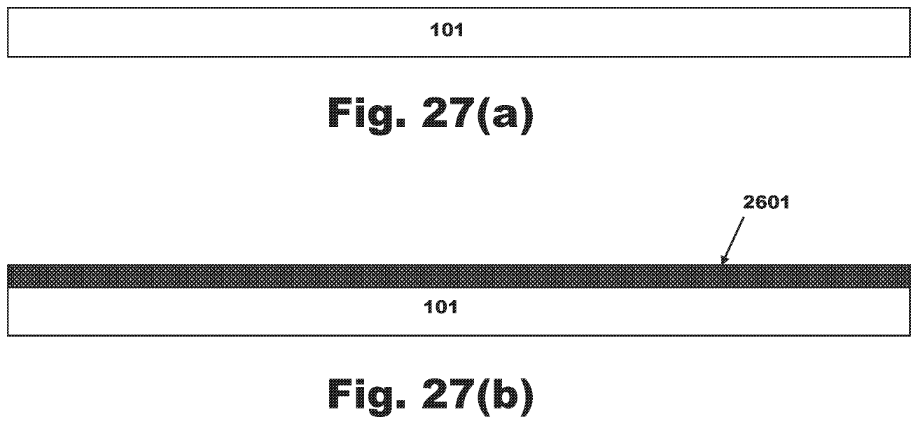

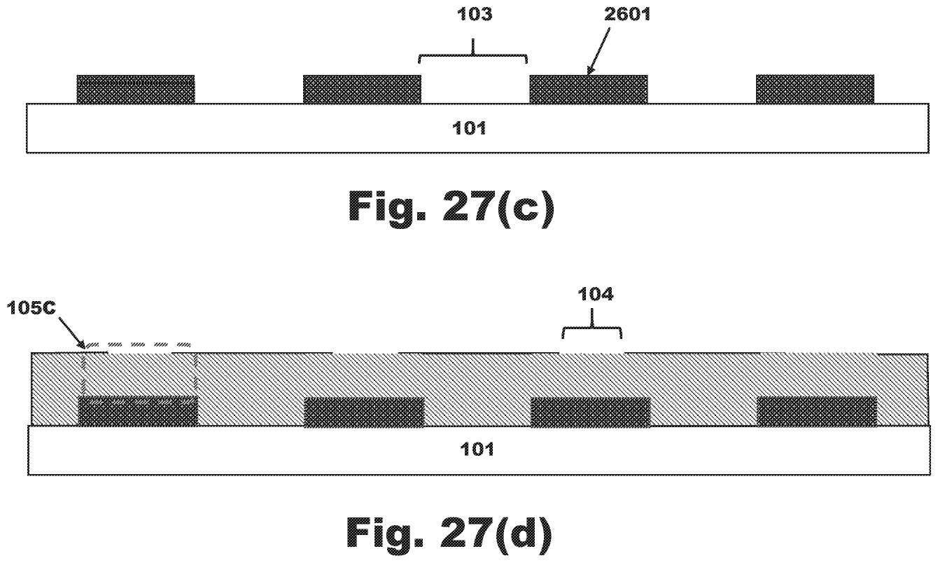

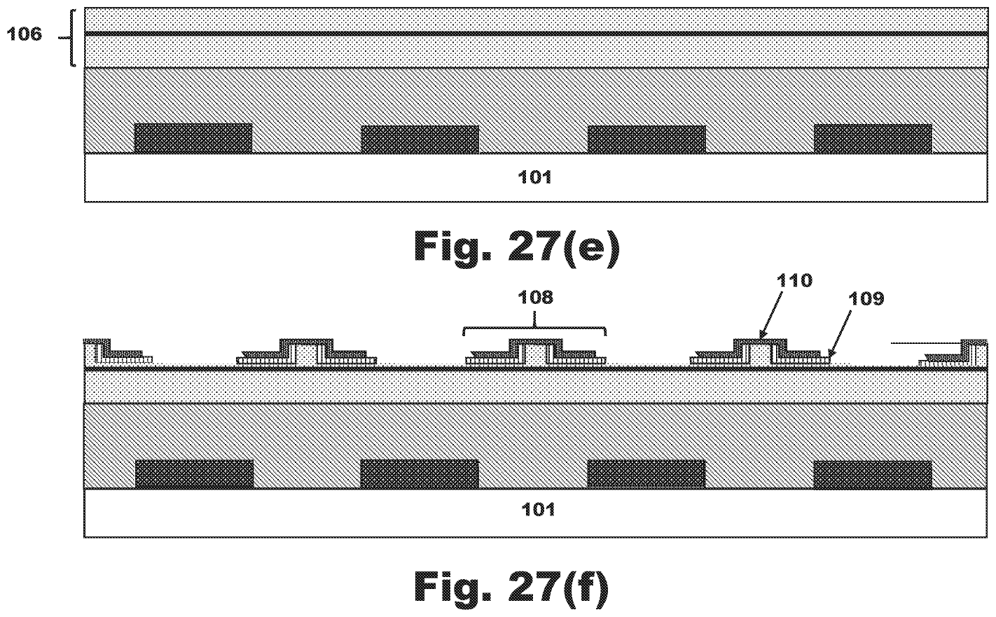

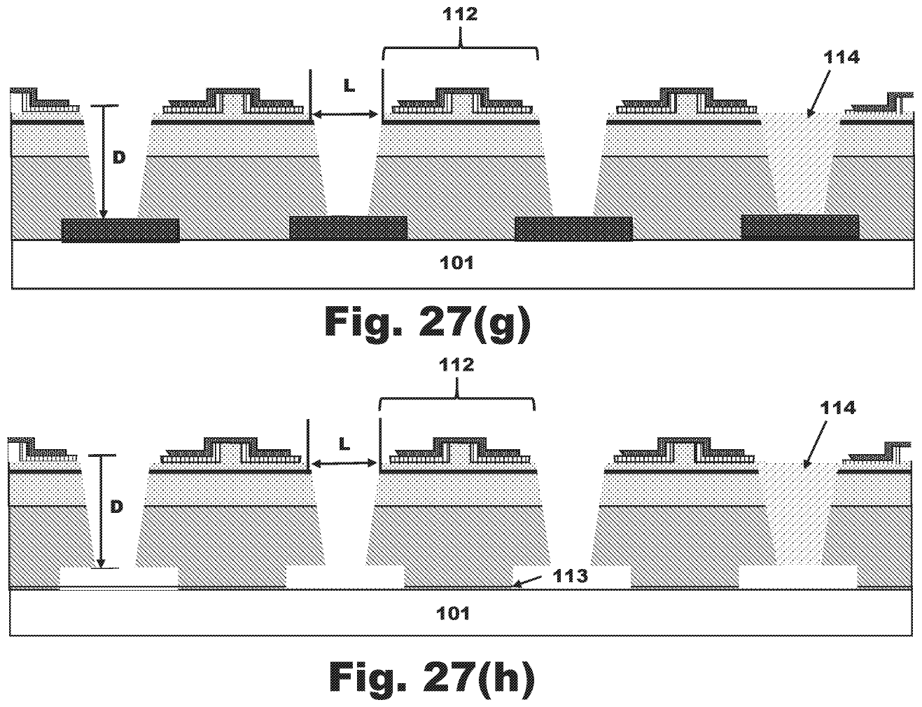

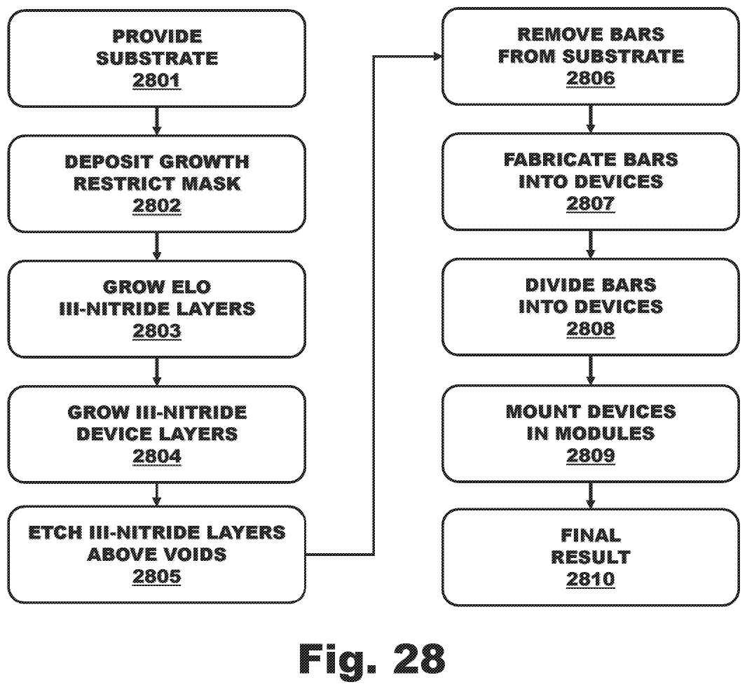

In an alternative approach, a growth support layer 2601 having a thickness of 10 nm to 1000 nm is deposited on the substrate 101, and the growth support layer 2601 is then patterned to have a plurality of striped openings 103 as shown in FIGS. 27(a), 27(b), 27(c), 27(d), 27(e), 27(f), 27(g) and 27(h).

Later, if Step 2, which comprises growing the ELO III-nitride layers 105A on the substrate using the growth restrict mask, is performed on this substrate 101 having a growth support layer 2601, then Step 3 and Step 4 can be skipped, and Step 5 can be performed directly. That means, after obtaining a flattened surface region over the substrate 101 containing the growth support layer 2601, one can directly grow III-nitride device layers 106 on top of this fully covered substrate 101, as indicated in FIGS. 26(e) and 27(e).

The III-nitride layer 106 grown over the growth support layer 2601 is chemically more reactive as compared to a III-nitride layer grown over the opening area 103, which will simplify the process of dividing III-nitride device layers 106. After forming a selective mask portion on area of interest 108, the substrate 101 can be dipped into a chemical solution, for example, heated KOH, HF, BHF, etc., to remove chemically reactive portions grown over the growth support layer 2601. This method at least exposes the native substrate 101 and leaves the device structures in the form of easy-to-remove shapes, as shown in FIGS. 26(h) and 27(h).

Alternatively, Step 7 as it is can be performed to obtain FIGS. 26(h) and 27(h). Of course, it can be used to etch the part of the region on the growth support layer 2601 using a conventional dry etching method.

In this embodiment, as shown in FIGS. 26(a) and 26(b), a base substrate 101 is first provided, and a growth support layer 2601 is deposited on top of a growth restrict layer 2602, for example, a dielectric layer, such as SiO₂, SiN, etc. Later, the growth support layer 2601 and growth restrict layer 2602 combination is patterned to have plurality of opening areas 103, as shown in FIG. 26(c). Alternatively, a similar approach can be followed by replacing the combination with a growth support layer 2601 only, as shown in FIGS. 27(a), 27(b) and 27(c).

A III-nitride ELO layer 105A may be grown on these growth support layer 2601 using MOCVD or HVPE. Thereafter, III-nitride device layers 106 may be grown to realize functional devices, such as a laser diode, LED, VCSEL, a device for power electronics, etc.

It is preferable that part of an active region, such as a ridge structure 108 or an emitting region of an LED, is on the opening area 103, because the region on the growth support layer 2601 has more dislocations as compared to the region on the opening area 103.

After fabricating III-nitride device layers 106 on the substrate 101 including the growth support layer 2601, the regions containing the growth support layers 2601 are etched from the top surface of the III-nitride device layers 106 to the surface of the base substrate 101 to divide individual device units. At least one individual device unit is removed mechanically from the base substrate 101 using the method of the other embodiments.

In this embodiment, the base substrate 101 is a c-plane substrate made of III-nitride-based semiconductor, which has a mis-cut orientation of −0.4 degrees towards an m-axis. Alternatively, this invention can be practiced on any substrate 101 independent of crystal orientation.

### Eighth Embodiment

This embodiment explains the triangular void method. Herein, the way is how to make the triangular voids.

In this embodiment, as shown in FIGS. 19(a) and 19(b), a substrate 101 is first provided, and a growth restrict mask 102 that has a plurality of striped openings areas 103 is formed on the substrate 101.

In this embodiment, the substrate 101 is a c-plane substrate made of III-nitride-based semiconductor, which has a mis-cut orientation with −0.4 degree towards the m-axis. In this embodiment, as shown in FIGS. 19(c), the opening area 103 width Wo and the growth restrict mask 102 width Wr are set to 5 μm and 50 μm, respectively, The thickness of the growth restrict mask 102 is 1.0 μm, and the width of etching area L is 15 μm. Since the depressed portion 1903 is a coalescence portion by contacting adjacent to the ELO III-nitride layers 105A, this portion has many defects. In this method, this region is eliminated by etching for the sake of the separation of the ELO III-nitride layer 105A and device layers 106. Thus, the defects in this portion do not affect the characteristics of the device, which is a great advantage.

The following explains the growth conditions of the initial growth layer and the ELO III-nitride layer 105A. First, the surface of the initial growth layer is elevated to above the growth restrict mask 102 in order to obtain the uniform shape of the ELO III-nitride layer 105A, as shown in FIG. 19(c). Since it does not need to have a high lateral growth rate, the initial growth layer has a higher V/III ratio than the ELO III-nitride layer 105A.

To achieve a high lateral growth rate, a low V/III ratio of less than 500 needs to be precisely controlled. However, an appropriate V/III ratio is changed depending on the growth temperature. The higher the temperature, the higher the VIM ratio is needed. The lateral growth rate can be achieved over 20 μm/hour, at a temperature ranging from 850° C. to 1250° C. The growth conditions are optimized to obtain a uniform shape for the ELO III-nitride layers 105A.

For example, the growth condition of the ELO III-nitride layer 105A may comprise the following: TEG=200 slm, NH₃=0.2 slm, growth temperature=1100° C., carrier gas is a mixed gas of N₂ and H₂. This layer is an unintentional doped (UID) layer. In this growth condition, there is a 1 hour and 30 minute growth of the ELO III-nitride layer 105A. After 2 hours of the growth of the ELO III-nitride layer 105A, adjacent ELO III-nitride layers 105A coalesce to each other. This can create the triangular shaped voids 107, as shown in FIG. 19(e) and FIGS. 21(a) and 21(b). The flattened surface on the substrate 101 including the ELO III-nitride layer 105A and the triangular shape voids 107 is shown in FIGS. 21(a), 21(b) and 21(c). There are not any cracks on the surface of the ELO III-nitride layer 105A. This is an evidence of the relaxation of the stress due to the existence of the triangular voids 107.

Afterwards, as shown in FIGS. 19(h), this method can fabricate devices on this substrate 101. And then, the region above the void 107 is eliminated by dry etching, as shown in FIG. 19(j).

In this embodiment, the bar 112 does not contain the center of the void region 107. The active region of the devices can be placed freely on the bar 112 due to the absence from the center of the void region 107.

The growth restrict mask 102 is dissolved by HF to facilitate removing the bars 112, as shown in FIG. 19(k). The bars 112 are removed from the substrate 101 using the adhesive tape 111 and the method mentioned before, as shown in FIGS. 19(l), 19(m) and 19(n). It is also possible to remove the bars 112 using another substrate bonded to the bars 112. This embodiment can also use the same process for packaging, as shown in FIGS. 12(a)-12(f) and FIGS. 13-18.

### Ninth Embodiment

This embodiment is almost the same process as the eighth embodiment except for the portion which is etched by dry etching to remove the bars 112. In this embodiment, the dry etching implements both parts, which are the portions above the void 107 and the opening area 103, as shown in FIGS. 22(a) and 22(b). The bar 112 does not contain the center of the void region 107 and the part above the opening area 103. The active region of the devices can be placed freely on the bar 112 due to its absence from the center of the void region 107 and the part above the opening area 103.

This helps devices to have high reliability. After etching, the bars 112 are on the growth restrict mask 102. The interface between the bottom surface of the ELO III-nitride layer 105A and upper surface of the growth restrict mask 102 do not have a strong bonding strength. Thus, to fix the bars 112 on the growth restrict mask 102, hooking layers 2202 are deposited on the photoresist 1905 as shown in FIG. 22(c). The part of the hooking layer 2202 on the photoresist 1905 is removed by a lift-off method, as shown in FIG. 22(d). By doing this, the bars 112 directly on the growth restrict mask 102 are fixed by the hooking layer 2202, which covers the side of the bar 112 and the surface of the growth restrict mask 102. This allows the substrate 101 to be further processed without peeling the bars 112 from the substrate 101.

Then, the bars 112 on the growth restrict mask 102 can be removed using several methods, such as the adhesive tape 111 method, as shown in FIG. 22(e), or the supporting plate 2203 method, as shown in FIG. 22(f), wherein the supporting plate 2203 is Si, Cu, etc., and the supporting plate 2203 uses a solder 2204, such as Au—Sn, Sn—Ag—Cu, etc.

In the supporting plate 2203 method, after contacting the supporting plate 2203 and the substrate 101 with bars 112, the bonded substrate 101 is heated to 230-300° C., and then is cooled down to room temperature. At this time, thermal stress fractures the hooking layer 2202 at the breaking point 113, as shown in FIG. 22(f), which allows the bar 112 to be removed from the substrate 101.

Thereafter, the same processes and packaging as shown in FIGS. 12(a)-12(f) and FIGS. 13-18 can be used.

Process Steps

FIG. 28 is a flowchart that illustrates a method for removing a bar 112 of one or more devices from a substrate 101 using void regions 107, wherein: one or more bars 112 comprised of III-nitride semiconductor layers 105A, 105B, 106 are formed on the substrate 101, and the devices' structures are formed on the bars 112; and stress is applied using the void regions 107 to remove the bars 112 from the substrate 101. The steps of the method are described in more detail below.

Block 2801 represents the step of providing a base substrate 101. In one embodiment, the base substrate 101 is a 111-nitride based substrate 101, such as a GaN-based substrate 101, or a hetero-substrate 101, such as a sapphire substrate 101. This step may also include an optional step of depositing a template layer on or above the substrate 101, wherein the template layer may comprise a buffer layer or an intermediate layer, such as a GaN underlayer,

Block 2802 represents the step of depositing a growth restrict mask 102 on or above the substrate 101. The growth restrict mask 102 is patterned to include a plurality of striped opening areas 103.

Block 2803 represents the step of growing one or more III-nitride layers 105A on or above the growth restrict mask 102 using epitaxial lateral overgrowth (ELO), followed by one or more III-nitride regrowth layers 105B. The growth of the ELO III-nitride layers 105A forms one or more void regions 107 on or above the substrate 101. This step may include removing any exposed areas of the growth restrict mask 102 by etching, and then growing the regrowth layer 105B on the ELO III-nitride layers 105A after the exposed areas of the growth restrict mask 102 are removed, thereby forming the void regions 107. This step may also include optimizing growth conditions during the growth of the ELO III-nitride layers 105A to make the void regions 108 in the ELO III-nitride layers 105A without removing the growth restrict mask 102. The ELO III-nitride layers 105A may be polished or flattened after growth of the regrowth layer 105B.

Block 2804 represents the step of growing one or more III-nitride device layers 106 on or above the ELO III-nitride layer 105A and III-nitride regrowth layer 105B, thereby fabricating a bar 112 on the substrate 101. Additional device fabrication may take place before and/or after the bar 112 is removed from the substrate 101. Block 2805 represents the step of etching the ELO III-nitride layers 105A, regrowth layer 105B and the III-nitride device layers 106 above the void regions 107 to at least expose at least part of the void regions 107.

Block 2806 represents the steps of removing the bar 112 from the substrate 101 using the void regions 107. Preferably, the bar 112 does not contain a center of the void regions 107.

Block 2807 represents the step of fabricating the bars 112 into devices after the bar 112 is removed from the substrate 101.

Block 2808 represents the step of dividing the bar 112 into one or more devices.

Block 2809 represents the step of mounting the devices in a package or module.

Block 2810 represents the resulting product of the method, namely, one or more III-nitride based semiconductor devices fabricated according to this method, as well as a substrate 101 that has been removed from the devices and is available for recycling and reuse.

The devices may comprise one or more ELO III-nitride layers 105A grown on or above a growth restrict mask 102 on a substrate 101, wherein the growth of the ELO III-nitride layers 105A is stopped before adjacent ones of the ELO III-nitride layers 105A coalesce to each other. The devices may further comprise one or more III-nitride regrowth layers 105B and one or more additional III-nitride device layers 106 grown on or above the ELO III-nitride layers 105A and the substrate 101.

Advantages and Benefits

The present invention provides a number of advantages and benefits, including, but not limited to, the following:

1. Semiconductor layers can be broken or cracked using the void regions without the use of the growth restrict mask.

2. The occurrence of holes can be avoided, when the Mg-doped layers coalesce.

3. A smooth surface can be obtained by chemical-mechanical polishing after the coalescence of the layers, which can eliminate the need for Mg-doped layers.

4. A laser diode structure can be processed on a flat surface of the layers.

5. The risk of edge-growth occurring can be eliminated.

6. A large chip size can be obtained using HVPE growth.

Modifications and Alternatives

A number of modifications and alternatives can be made without departing from the scope of the present invention.

For example, the present invention may be used with III-nitride substrates of other orientations. Specifically, the substrates may be basal nonpolar m-plane {1 0-1 0} families; and semipolar plane families that have at least two nonzero h, i, or k Miller indices and a nonzero l Miller index, such as the {2 0-2-1} planes. Semipolar substrates of (20-2-1) are especially useful, because of the wide area of flattened ELO growth.

Moreover, the present invention can use various kinds of hetero-substrates such as the III-nitride layer on the sapphire substrate, the silicon substrate, and the SiC substrate and so on. It is possible to grow the ELO III-nitride layer 05A on the sapphire substrate with the growth restrict mask directly.

In another example, the present invention is described as being used to fabricate different opto-electronic device structures, such as a light-emitting diode (LED), laser diode (LD), Photo diode (PD), Schottky barrier diode (SBD), or metal-oxide-semiconductor field-effect-transistor (MOSFET). The present invention may also be used to fabricate other opto-electronic devices, such as micro-LEDs, vertical cavity surface emitting lasers (VCSELS), edge-emitting laser diodes (EELDs), and solar cells.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method, comprising:
growing one or more epitaxial lateral overgrowth (ELO) III-nitride layers on the substrate, wherein the ELO III-nitride layers coalesce to create one or more voids between a surface of the substrate and a surface of the ELO III-nitride layers;
growing one or more III-nitride device layers on or above the ELO III-nitride layers;
etching the ELO III-nitride layers and the III-nitride device layers above the voids to at least expose the voids; and
removing a bar comprised of the ELO III-nitride layers and the III-nitride device layers from the substrate at the exposed voids.

2. The method of claim 1, wherein the ELO III-nitride layers include a regrowth layer and/or a flattening layer.

3. The method of claim 2, wherein the regrowth layer and/or the flattening layer includes Magnesium (Mg).

4. The method of claim 2, wherein the ELO III-nitride layers are polished after growth of the regrowth layer.

5. The method of claim 1, wherein the bar does not contain a center of the voids.

6. The method of claim 1, wherein one or more devices are fabricated from the bar.

7. A structure, comprising:
one or more epitaxial lateral overgrowth (ELO) III-nitride layers grown on the substrate, wherein the ELO III-nitride layers coalesce to create one or more voids between a surface of the substrate and a surface of the ELO III-nitride layers;
one or more ill-nitride device layers grown on or above the ELO III-nitride layers;
the ELO III-nitride layers and the III-nitride device layers above the voids are etched to at least expose the voids; and
a bar comprised of the ELO III-nitride layers and the III-nitride device layers is removed from the substrate at the exposed voids.

8. A method, comprising:
growing one or more epitaxial lateral overgrowth (ELO) III-nitride layers on or above a substrate, wherein growth of the ELO III-nitride layers forms one or more voids on or above the substrate;
growing one or more III-nitride device layers on or above the ELO III-nitride layers;
etching the III-nitride device layers and the ELO-nitride layers to expose at least part of the voids; and
separating a bar comprised of the III-nitride device layers and the ELO III-nitride layers from the substrate at the exposed part of the voids.

9. The method of claim 8, wherein the voids are formed by:
depositing a growth restrict mask on a surface of the substrate;
growing the ELO III-nitride layers on the substrate through one or more opening areas in the growth restrict mask, wherein growth of the ELO III-nitride layers is stopped before the ELO III-nitride layers coalesce and/or the growth restrict ask is completely covered by the ELO III-nitride layers;
removing any exposed areas of the growth restrict mask by etching; and
growing a regrowth layer on the ELO III-nitride layers after the exposed areas of the growth restrict mask are removed, thereby forming the voids.

10. The method of claim 9, wherein the voids release stress resulting from the growth restrict mask.

11. The method of claim 9, wherein decomposition of the growth restrict mask is avoided, which avoids compensation of p-type layers in the III-nitride device layers.

12. The method of claim 9, wherein a depressed portion at a no-growth region is buried by the regrowth layer, which flattens a surface of the regrowth layer.

13. The method of claim 9, wherein the regrowth layer is doped with Magnesium (Mg) to reduce a number of holes at a surface of the regrowth layer.

14. The method of claim 8, wherein the voids are formed by:
optimizing growth conditions during the growth of the ELO III-nitride layers to make the voids in the ELO III-nitride layers without removing a growth restrict mask.

15. The method of claim 14, wherein the growth conditions form facets at an edge of the ELO III-nitride layers, and the facets comprise inverted taper shapes.

16. The method of claim 15, wherein the inverted taper shapes create the voids that are triangular shapes at a coalescence region of the ELO III-nitride layers.

17. The method of claim 8, wherein stress is applied to separate the bar from the substrate.

18. The method of claim 17, wherein the stress is applied at the voids.

19. The method of claim 8, further comprising smoothing the surface of the ELO III-nitride layers.

20. The method of claim 8, wherein one or more devices are fabricated from the bar.
